(19) United States
(12) Patent Application Publication
(10) Pub. No.: US 2026/0126473 A1
(43) Pub. Date: May 7, 2026

(54) Monitoring Electrical Load

(71) Applicant: Inframesh Limited, London (GB)

(72) Inventor: Adam VERSTEEGH, London (GB)

(21) Appl. No.: 19/383,228

(22) Filed: Nov. 7, 2025

Related U.S. Application Data
(63) Continuation of application No. PCT/GB2024/051453, filed on Jun. 5, 2024.

(30) Foreign Application Priority Data
Jun. 5, 2023 (GB) 2308379.3
Dec. 22, 2023 (GB) 2320019.9

(51) Int. Cl. G01R 15/18; G01R 19/00

(52) U.S. Cl. CPC G01R 15/18; G01R 19/0092

(57) ABSTRACT

Disclosed is an apparatus for monitoring electrical load in a building. The building has a primary electricity supply that is split into a plurality of individual electrical circuits. The apparatus includes a first sensing circuit configured to sense electrical load in a first electrical circuit of the plurality of individual electrical circuits and an analogue to digital to converter (ADC) configured to measure the electrical load at the first sensing circuit at a sampling rate greater than or equal to 18 kHz.

### PRIORITY APPLICATIONS

This application is a continuation of PCT Application PCT/GB2024/051453, filed Jun. 5, 2024, titled “Monitoring Electrical Load,” which claims priority to (i) GB Application No. 2320019.9, filed Dec. 22, 2023 and (ii) GB Application No. 2308379.3, filed Jun. 5, 2023. Each of these three applications is incorporated by reference herein in its entirety.

### TECHNICAL FIELD

The present disclosure relates to monitoring electrical loads. Aspects of the invention relate to an apparatus, a computer-implemented method, and a system for monitoring electrical load in a building.

### BACKGROUND

Buildings such as offices, warehouses, and residential buildings have a primary building power supply (e.g. Mains power) that supplies many individual electrical circuits. Each electrical circuit connects multiple different electrical appliances. Building owners and users have started to use systems to monitor the electrical load in a building, in order to attempt to manage energy usage, carbon footprint and reduce running costs.

### SUMMARY OF THE INVENTION

Building owners and users use systems to monitor and control energy consumptions in offices, warehouses and even residential buildings. These are known as Building Energy Management System (BEMS).

There are several different known ways in which a BEMS has been used to seek to reduce electrical usage. For example, some BEMS which control lighting also include Passive InfraRed (PIR) sensors to turn on lights when a user is detected in the vicinity of the PIR sensor. In this way, the lighting can default to being in an off state (consuming no energy) and only be switched on when needed, namely when a user is detected in the vicinity of the PIR sensor. These solutions are effective but are entirely passive when it comes to changing user behaviour. This is not only because there, the only interaction with the user is the sensing of their presence, but also because there is no user identification required to trigger the PIR sensor. Also, this type of solution is used for lighting as well as other applications, for example zoned HVAC.

Other ways in which BEMS can save electricity is by the use of smart plugs, specific circuit boards, learning thermostats and autonomous lighting (such as the PIR system described above) which are designed to reduce energy waste or remove it entirely. For example, smart circuits (built into devices) or smart plugs (through which devices are powered) know when to stop powering unused devices or chargers. Learning thermostats dynamically adjust the temperature on demand in different areas instead of cooling or heating the unused spaces. Smart plugs, timers, or other controllers for lighting often use significant power, both when in use and in a standby state. Having many of these increases the phantom load of a building and produces more heat, which can increase cooling costs of the building.

There is a growing desire for owners and users of different buildings both commercial and residential to reduce energy usage and costs, increase energy security, and save money. Building owners and users have started to use different systems (some described above) to control and monitor energy consumptions in offices, warehouses and even residential buildings. At the moment, there are many solutions on the market that can really help to save energy consumption, but they do not meet all the needs of end users and have disadvantages, such as:
i) High cost of installation;
ii) Need for skilled installation;
iii) Considerable amount of time required for installation;
iv) Specific skills needed for installation;
v) Poor UI (user interfaces) and a lack of features for the end user;
vi) High cost of hardware, for example dependence on costly smart plugs and/or costly light sensors;
vii) low accuracy;
viii) Bespoke nature of installation, for example focused only on the specific type of property;
ix) Heavy configuration/integration effort needed between disparate hardware (e.g. smart plugs) and the wider system;
x) not user specific, aimed ONLY at facility managers, and not at end-users; and
xi) prone to tampering (e.g. by end users removing smart-plugs and the like).

The present disclosure is directed to a Building Energy Management System (BEMS) that can be used to monitor and manage the mechanical, electrical, and electromechanical services in a facility, such as a building. The present disclosure has application to sub-appliance/sub-load monitoring, and also to a new improved electrical meter with a higher degree of fidelity. The present disclosure is further directed to a BEMS which seeks to reduce electricity costs, can be applied to a variety of building types, and can provide a reward system for end-users.

According to a first aspect herein, there is an apparatus and a method for monitoring electrical load in a building. In the present invention, a sensor senses electrical load in a first circuit in the building, e.g. in an individual electrical circuit of a building (e.g. at a circuit-level), at a sampling rate greater than or equal to 18 kHz.

Previous BEMS have attempted to monitor loads by monitoring the load signatures on the Mains power supply of the building, however, the Mains power supply is extremely noisy and the large number of loads thereon makes it very difficult to isolate individual signals therein, particularly if the individual signals are from low-load appliances, or there is more than one device of a particular type (e.g. more than one low-load appliance).

The combination of circuit-level monitoring and the higher sampling rates used in embodiments herein capture signals with sufficient resolution to be able to distinguish between different electrical appliances connected to the individual electrical circuits. In particular, it has been found that circuit-level monitoring, at these sampling rates, provides a signal of sufficient resolution for machine learning models to be able to split each signal into the individual load signatures of the appliances or devices on each circuit, even for low-loads or scenarios where there are multiple low-loads of the same type.

In some embodiments, the sampling rate is greater than 1 MHz. Sampling at rates greater than 1 MHz (or between 1 MHz and 5 Mhz), allows the detection of transients and harmonics of low-load devices. This allows individual loads to be identified, even when there is more than one low-load device connected to the circuit. It further allows two or more low-loads to be distinguished from one another, even if they are of the same type of device (e.g. such as the same make and model of device/laptop/mobile phone etc) and thus inherently have very similar load characteristics. In this way, particularly fine grain measurements can be made and used to collect data on electricity usage on a device-by-device manner, using circuit-level load measurements. Also, the design of any such new meter incorporating the sensing circuits described herein is independent of any positional system and can provide benefit by disaggregating electrical loads on a circuit for analysis without the need for positional information being available.

Using high sampling rates significantly enhances appliance identification by capturing detailed electrical signatures and harmonics, which are critical for precise differentiation. This enables the system to distinguish between similar appliances, such as coffee machines and kettles, and those with variable consumption patterns, like heat pumps or Ambilight TVs. High sampling rates improve the detection of transient events, low-power devices, and appliances in high-load environments, reducing misclassification and enhancing algorithm performance. By analyzing harmonics and other signal features, Non-Intrusive Load Monitoring (NILM) systems can differentiate between appliances of the same type based on their unique harmonic profiles. Systems that do not offer high sampling rates face limitations, such as difficulty in accurately identifying appliances, distinguishing between similar devices, detecting variable loads, and capturing low-power devices, leading to higher rates of misclassification and/or missed appliances (unidentified loads), and less effective energy management.

High sampling rates enable the use of statistical methods to average out noise over multiple samples. This process, known as oversampling, reduces the impact of random noise on the measurements. Moreover, Advanced algorithms for NILM can leverage high-resolution data to better model and predict appliance behavior, making them more robust against noise. These algorithms can use machine learning techniques to learn the difference between noise and actual appliance signatures over time.

In some embodiments, the sampling rate is between about 1 MHz and about 5 MHz; or between about 1 MHz and about 2 MHz.

In some embodiments, the analogue to digital converter is at least 12-bit.

In some embodiments, the first sensing circuit comprises a ferrite core that can be affixed around a portion of the first electrical circuit and a coil that winds around at least a portion of the ferrite core. In such embodiments, the coil non-obtrusively detects current fluctuations in the portion of the first electrical circuit.

In some embodiments, the apparatus further comprises a second sensing circuit configured to sense voltage fluctuations through resistive or capacitive techniques. In some embodiments, the apparatus further comprises an auto-gain adjuster.

In some embodiments, the ADC is further configured to output a signal comprising the sensed electrical load to a controller.

In some embodiments, the sampling rate is set dependent on:—a number of loads connected to the first electrical circuit; and/or—load characteristics of the loads connected to the first electrical circuit.

For example, the sampling rate may be set to a higher rate when a first number of appliances are connected to the first electrical circuit compared to when a second number of appliances are connected to the first electrical circuit, wherein the first number of appliances is greater than the second number of appliances.

As another example, the sampling rate may be set higher if there is more than one appliance of the same type on the first electrical circuit compared to if each appliance on the first electrical circuit is of a different type.

As another example, the sampling rate may be set higher if one or more of the appliances connected to the first electrical circuit is a low load appliance compared to if the appliances are high load appliances.

In some embodiments, the building has a primary electricity supply that is split into a plurality of individual electrical circuits, and the first electrical circuit is one of said individual electrical circuits. In other words, the first sensing circuit performs circuit-level sampling.

In a second aspect there is a computer-implemented method for monitoring electrical load in a building, the method comprising: receiving a signal from a first sensing circuit of an electrical load on a first electrical circuit in the building, wherein the signal has a sampling rate of at least 18 kHz; and determining one or more loads that are connected to the first electrical circuit from the signal from the first sensing circuit.

In some embodiments, the signal has a sampling rate of between about 1 MHz and about 5 MHz; or between about 1 MHz and about 2 MHz.

In some embodiments, the method further comprises: determining a number of loads connected to the first electrical circuit and/or load characteristics of the one or more loads connected to the first electrical circuit; and sending an instruction to an analogue to digital converter, ADC, to set the sampling rate of the ADC, according to the determined number of loads and/or the load characteristics.

In some embodiments, the step of determining one of more loads comprises: determining one or more appliances on the first electrical circuit based on load signatures in the received signal using mixed deep learning models, Fast Fourier Transform (FFT) and/or techniques related to Nonintrusive Load Monitoring (NILM); wherein a load signature corresponds to a change in electrical load on the first electrical circuit when an appliance is activated.

In some embodiments, the step of determining comprises using a model trained using a machine learning process to determine the one or more loads from the signal from the first sensing circuit.

In some embodiments, the step of using a model comprises: determining one or more sub-signals in the signal from the first sensing circuit, corresponding to one or more loads connected to the first electrical circuit; and classifying the one more sub-signals according to load type.

In some embodiments, the model classifies the one or more sub-signals based on transients and harmonics in the one or more sub-signals.

In some embodiments, the method further comprises determining an unknown sub-signal in the signal; sending a request for a user to supply a first user input identifying an appliance associated with the unknown sub-signal; receiving the first user input identifying the unknown sub-signal; and using the label and the unknown sub-signal as training data with which to further train the model.

In some embodiments, the model further takes as input data relating to an appliance age, temperature, humidity and/or other environmental conditions.

In some embodiments, the method further comprises: obtaining acoustic signatures in the physical vicinity of the first circuit; and predicting locations of the one or more appliances in the building, by matching the one or more appliances to the acoustic signatures.

In some embodiments, the method further comprises: obtaining mobile device data (e.g. from a camera or audio capture equipment therein) of a user in the physical vicinity of the first circuit; and predicting locations of the one or more appliances in the building, from the mobile device data.

In some embodiments, the method further comprises: providing a recommendation to the user of an action that could be taken by the user to i) reduce the energy consumption of the first electrical circuit, ii) manage the health of the one or more loads in the vicinity of the location of the user; and/or iii) perform maintenance on the one or more loads in the vicinity of the location of the user. This may be performed by: matching the locations of the one or more appliances to a location of the user; and determining an action that might be performed by the user on the matched appliances. In some embodiments, the recommendation is determined by a second machine learning model.

In some embodiments, the method further comprises: determining that one of the one or more loads is damaged or malfunctioning, from electrical noise detected in the respective load's signature. The determination may then be e.g. sent to a user.

According to an aspect herein there is a system for monitoring electrical load in a building. The system comprises: a first sensing circuit configured to sense electrical load in a first electrical circuit in the building; an analogue to digital converter configured to measure the electrical load at the first sensing circuit at a sampling rate greater than or equal to 18 kHz; and one or more processors configured to: determine one or more loads that are connected to the first electrical circuit from the signal from the first sensing circuit.

According to another aspect there is a method of monitoring electrical load in a building, the method comprising: sensing the electrical load on a first electrical circuit using an apparatus as in the first aspect; and determining one or more loads connected to the first electrical circuit, based on the signal from the first sensing circuit in said apparatus.

According to another aspect there is a method for monitoring electrical load in a building, the method comprising: receiving a signal from a first sensing circuit of an electrical load on a first electrical circuit in the building, wherein the signal has a sampling rate of at least 18 kHz; determining one or more loads that are connected to the first electrical circuit from the signal from the first sensing circuit; determining a location of a user in the building; and sending a recommendation to the user to perform an action with respect to one or more loads in the vicinity of the location of the user to i) reduce the energy consumption of the building; ii) manage the health of the one or more loads in the vicinity of the location of the user; and/or iii) perform maintenance on the one or more loads in the vicinity of the location of the user.

In some embodiments, the first sensing circuit is non-intrusive and the system acts as a non-intrusive recommender system for load management on the first circuit.

According to another aspect there are computer readable instructions which, when executed by one or more processors, cause the one or more processors to perform any of the method aspects described above.

### BRIEF DESCRIPTION OF THE DRAWINGS

One or more embodiments of the invention will now be described, by way of example only, with reference to the accompanying drawings, in which:

FIG. 1A is a block diagram showing components of an electrical load monitoring system in accordance with an embodiment of the present invention;

FIG. 1B shows the system of FIG. 1A in greater detail;

FIG. 1C is a block diagram illustrating an electrical load monitoring system in accordance with an embodiment of the present invention;

FIG. 2A is a circuit diagram of an electrical sensing circuit used in the system of FIGS. 1A and 1B.

FIG. 2B is a circuit diagram of the apparatus of FIG. 1C;

FIG. 3 shows an example computer node according to an embodiment of the present invention;

FIG. 4 shows an example method performed by a computer program in some embodiments herein;

FIG. 5 shows an example method according to some embodiments herein;

FIG. 6A shows an example floor plan according to some embodiments herein;

FIG. 6B shows an example floor plan according to some embodiments herein;

FIG. 6C shows an example method performed by a recommender system according to some embodiments herein; and

FIGS. 7A-C, 8 A-D, 9A-E, 10A-D and 11 show various experimental results related to the experiment in the Appendix.

### DETAILED DESCRIPTION

As described above, there is a need to monitor electrical load in a building, so that appropriate actions can be taken to manage energy consumption for environmental purposes, as well as to reduce running costs of the building. A common method is to use smart plugs, into which electrical loads are plugged. The smart plug measures the electrical load of the device plugged into it. However, the type of electrical loads that can be monitored using smart plugs is limited: electrical loads that do not plug into a socket (for example room lighting) cannot be monitored in this way. Additionally, smart plugs are not designed to measure low load or resistive load, which again limits the types of loads that they can be used for. Smart plugs are also intrusive, as the smart plugs themselves draw current, using significant power both when in use and in a standby state. Thus, the measured load is not accurate. Furthermore, such methods require large numbers of said smart plugs which can be expensive and inconvenient to install.

While some non-intrusive load monitoring methods exist, these typically measure electrical load of the building as a whole, e.g. by making measurements on the Mains power supply to the building. Thus, limited information on individual floors, rooms, and appliances is available, and the measured signal is noisy. Noise in power line measurements can mask true appliance signals, complicating identification. Additionally, commercial buildings present specific challenges: they have hundreds of small, similar loads, making identification and quantification difficult; small changes in power consumption provide ambiguous information; and many devices drawing power continuously are not detectable by current NILM algorithms.

The present disclosure addresses the above-described challenges. Herein it has been recognised that individual loads in a building can be monitored in a centralised, non-intrusive manner, without the need for individual smart plugs, by: i) by placing non-intrusive sensors at a circuit-level in the building (e.g. rather than on the Mains power supply, or on a device level); and ii) by using an analogue to digital converter (ADC) that samples the sensor at a high sampling rate, e.g. at a rate greater than or equal to 18 kHz. In this way, circuit-level load signals can be obtained with sufficient resolution that they can be split into their component parts by e.g. machine learning methods. This has significant advantages, as it allows for centralised monitoring (e.g. via/at the level of the building's consumer unit) of all loads (e.g. devices or appliances) in a building, without the need to attach individual sensors to each and every load. This is described in more detail in the following example embodiments.

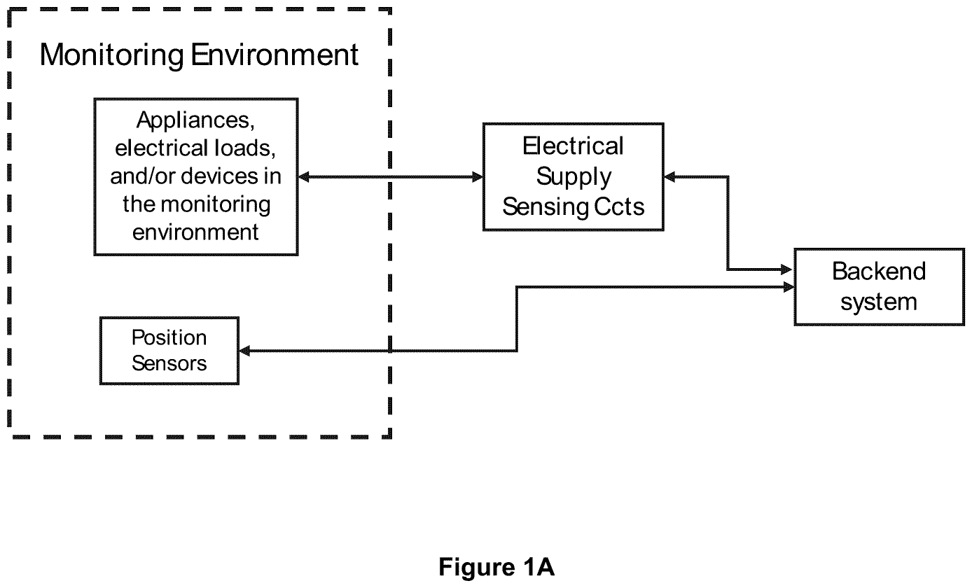

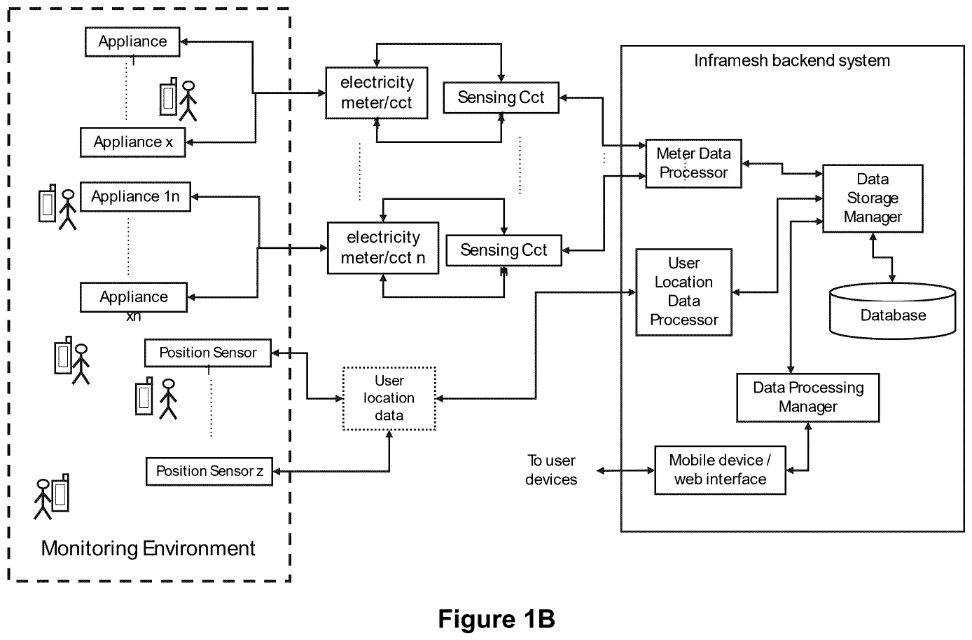

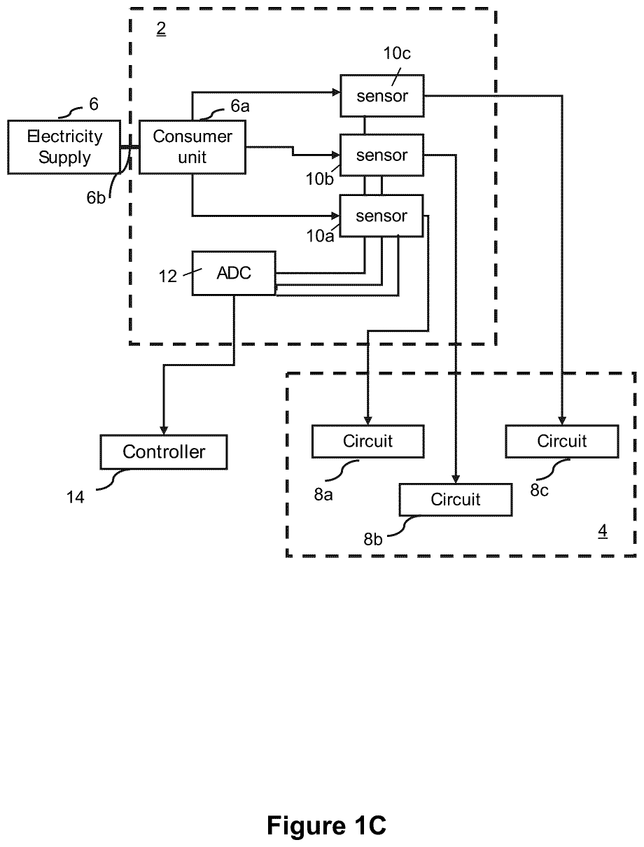

FIG. 1A shows the high-level components of a system according to one embodiment of the present invention. Within a monitoring environment multiple appliances (electrical loads) may be provided. Each of these appliances is supplied with electricity via an electrical circuit. The supply of electricity is monitored by non-intrusive electrical supply sensing circuits which sense the electrical usage of each appliance. As these sensing circuits are non-intrusive, they enable this part of the system to advantageously be retrofitted to existing electrical meters. These sensing circuits in turn provide that data to a backend system for processing. The amount of data supplied can vary as some of the raw data can be processed locally at the sensing circuit to reduce the data load that is required to be communicated to the backend. Similarly, position sensors are also provided within the monitoring environment, which monitor the location of users within that environment. That position data is provided back to the back-end system for processing. The back-end system can then associate a specific change in appliance energy consumption as detected by the electrical supply sensing circuits and associated that with the location of a user to determine the user's interaction with the electrical appliance and its effect on electrical supply consumption. It is to be appreciated that in another embodiment the position sensors can be avoided by using location determining sensors in the portable mobile telecommunications devices of the users (occupants) within the monitoring environment. For example, in some embodiments it is possible to use a GPS sensor of the mobile device either alone or in combination with the positioning sensors to provide location data about the user and then associate that location information with the user-interaction locations (touchpoints) of anything that generates an electrical load (for example an appliance). All the system needs with respect to users is positional information regarding the user and a knowledge of the touchpoints within the monitoring environment.

Referring to FIG. 1B, where the system of FIG. 1A is shown in more detail, each circuit is monitored by an electricity consumption meter. Each meter is monitored by a sensing circuit which clamps onto existing wiring around a meter or sensing circuit and so is easily able to be retrofitted to existing electrical supplies. In alternative embodiments, it may not be necessary to clamp the existing wires around a meter as the meter may be designed to provide the required resistive and inductive sensed signals for use by the sensing circuit.

The sensing circuits sample the electrical circuit at a high-frequency (typically 1-5 MHz, more preferably 1 to 2 MHz) and monitor variations in the sensed signals by an event occurring in that circuit. As the power consumption of a device changes, for example by being switched on or off, this generates a unique electrical signature within the electrical supply which is seen in changes in the sensed High-Frequency signal. By analysing this change in the sensed signal, each different appliance can be identified as each has a different signature. This is described in greater detail in the proof-of-concept section of this disclosure described in the Appendix.

In FIG. 1B, each sensing circuit is shown as being operatively coupled to the back-end system. This connection can be carried out in a number of different ways including each sensing circuit being an IoT device with its own internet address and therefore the data can be sent via the Internet to the backend system. More preferably, the sensing circuits can communicate with the Cloud (networked computing facilities providing remote data storage and processing services via the internet) and the sensing data or edge processed sensing data can be stored to the Cloud and then provided to the backend system for processing. In further embodiments, the data processing of backend system can also be implemented in the Cloud.

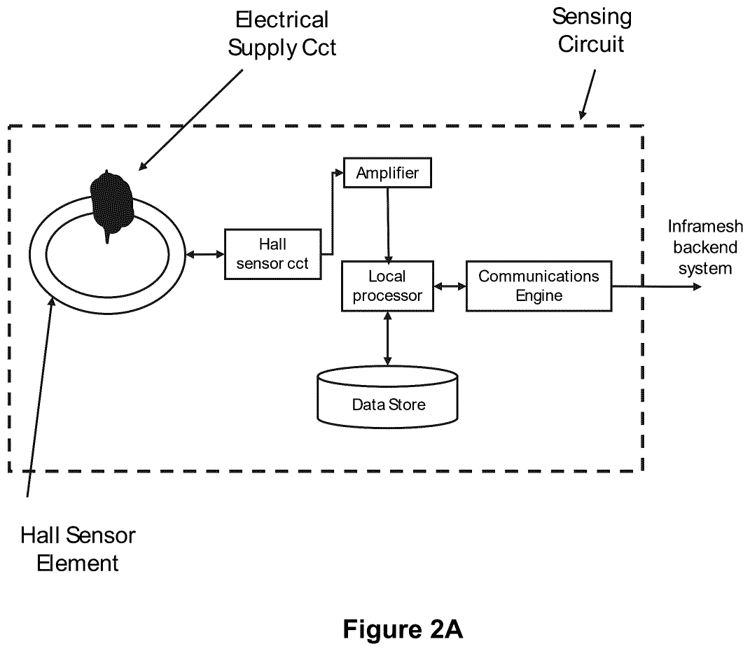

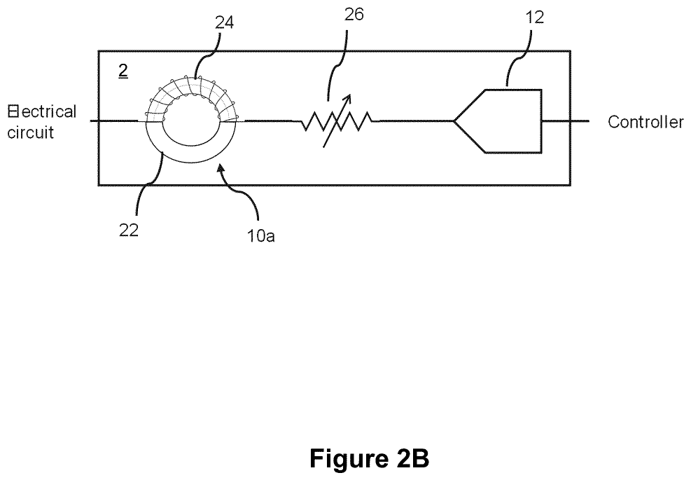

The novel sensing circuit of the present embodiment monitors up to n individual circuits at a sampling rate greater than 18 KHz, (or in some embodiments, at a sampling rate between 1 Mhz-5 Mhz), in one embodiment n=16. Each circuit has a variable number (x or y as shown in FIG. 1B) of electrical appliances (or electrical loads) which it can handle. Each of these circuits can be associated with a specific electrical meter (as shown in FIG. 1B) or can be a circuit within a multi-circuit meter. It is also possible for the electrical meter to be modular in terms of the number of different electrical circuits it can handle. In this case each of the modular electrical circuits would have a corresponding sensing circuit. In another embodiment, the sensing meter is integrated into the electricity meter. An example of the hardware which could be used for sensing at a high-frequency sampling rate inductive and resistive load variations of electrical supply on a given circuit is provided later in FIG. 2A. Such a sensing meter uses a shunt resistive load and an inductive choke for sensing different frequency variations in the circuit. This enables the system to monitor events regarding with the electrical loads on the circuit and determine a change of state of that electrical load from detecting a specific profile signatures of sensed frequency changes. Whilst in theory it would be possible to provide all of the raw data to the backend system for processing, for example in the cloud, given the amount of data that is generated, edge processing can be used in the sensing circuit.

FIG. 1C is a block diagram illustrating an apparatus 2 for monitoring electrical load in a building 4 according to another embodiment of the present invention. The building 4 has a primary electricity supply 6. As used herein, the primary electricity supply refers to the ‘Mains’ power supply of the building, e.g. the connection to the external electrical grid.

Buildings can be domestic buildings such as homes or home-offices; or commercial buildings such as office blocks, factories, manufacturing plants, or any other type of building.

In a domestic building, the primary power supply 6 may be fed into an electrical consumer unit 6a (which may otherwise be referred to herein as a distribution unit) that powers a plurality of individual electrical circuits (8a, 8b, 8c). In a commercial building, the primary power supply may be split into e.g. 3 phases (at point 6b) which are each connected to a respective consumer unit 6a and which each power a respective plurality of individual electrical circuits (8a, 8b, 8c).

As shown in FIG. 1C, the apparatus 2 comprises a first sensing circuit 10a configured to sense electrical load in a first electrical circuit 8a of the plurality of individual electrical circuits, and an analogue to digital converter 12 configured to measure the electrical load at the first sensing circuit 10a at a sampling rate greater than or equal to 18 kHz. In FIG. 1C, the apparatus 2 further comprises a second sensing circuit 10b configured to sense electrical load in a second electrical circuit 8b of the plurality of individual electrical circuits, and a third sensing circuit 10c configured to sense electrical load in a third electrical circuit 8c of the plurality of individual electrical circuits. It will be appreciated that three circuits is merely illustrative however and that any number of circuits may be monitored using the methods described herein.

In FIG. 1C, the first, second and third sensing circuits sense current (e.g. the current waveform) in the first, second and third electrical circuits respectively. There may be further sensing equipment to that illustrated in FIG. 1C, for example, In some embodiments, the voltage waveform is also obtained. Voltage can be sensed, for example, by resistive and/or capacitive techniques. This can be performed through the power source of the circuit sensing hardware.

For voltage sensing, two example approaches are as follows. In a first approach, Voltage Transformers (VTs) can used: Similar to CTs, VTs reduce the high voltage from the mains supply to a safer, lower voltage that can be measured by the NILM device. They ensure electrical isolation and protect the device from damage.

In a second approach, Resistive Voltage Dividers can used: These simple circuits use resistors to divide the voltage proportionally, making it easier to measure. They are often used in combination with voltage transformers to further reduce the voltage to a level suitable for analog-to-digital conversion.

Herein, the total electrical load measured on the first circuit is decomposed, or split into the individual loads associated with the appliances or devices connected to the first circuit. An electrical load (which may otherwise be referred to herein as an appliance, or device) is any component, e.g. electrical appliance or device, that is electrically connected to a circuit 8a, 8b, 8c, and consumes electrical energy. Examples of loads include, but are not limited to: elevator or escalator systems in a commercial building, air-conditioning units, computer servers, fridges, dishwashers, tumble dryers, printers, computers, televisions, and wi-fi routers. In some embodiments, the term ‘appliance’ is intended to mean any electrical system or device generating an electrical load which can be controlled in some manner by human interaction. Examples include an electrical heating system, printer, computer, lighting, air conditioning unit, a monitor, etc.

As used herein, “low-load” is used to denote devices or appliances that draw comparatively low current. Examples include, but are not limited to laptop computers, wifi routers, lamps and the light. These sorts of load draw orders of magnitude lower current compared to, for example, an elevator system, or air conditioning unit. Circuit-level monitoring at the sampling rates determined herein allow low-load appliances less than 100 W (or even less than 50 W) to be monitored.

Some loads in a building are connected to particular circuits 8a, 8b, 8c, for example, there may be a “lighting circuit”. Furthermore, some circuits 8a, 8b, 8c may be associated with particular locations in a building, for example, a different circuit may be associated with each floor of a building.

As mentioned briefly, the first sensing circuit 10a is configured to sense electrical load in a first electrical circuit 8a of the building. The first electrical circuit may be one of a plurality of individual electrical circuits in the building. The first electrical circuit may come off a distribution unit (otherwise known as a consumer unit). As such, the first sensing circuit may be installed at the electrical distribution panel. There may be different sensing circuits installed/attached to each separate positive cable. As such, each positive cable therein may be fitted with its own sensing circuit. In other words, the first sensing circuit 10a is configured to measure the electrical load in one sub-circuit 8a of the multiple electrical circuits supplying the building 4. Similarly, the sensing circuits 10b and 10c are configured to sense the electrical load in individual circuits 8b and 8c respectively. In this way, the electrical load at a circuit-level is measured.

In some embodiments, the first sensing circuit 8a (and/or sensing circuits 8b, 8c) comprises a coil. A coil is a passive sensor, which draws no current from the electrical circuit. Therefore, the sensed inductive load on the first electrical circuit (sub-circuit) 8a is more likely to be an accurate representation of the electrical loads connected to the first electrical circuit 8a. Other types of sensor capable of sensing inductive load may equally be used, for example a Hall sensor. (However, a Hall sensor itself draws current from the electrical circuit, affecting the measurement.) Example sensing circuits are described in more detail below with respect to FIGS. 2A and 2B.

Turning to the analogue to digital converter 12, the analogue to digital converter 12 is configured to receive the electrical load signal (e.g. current signal) from the first sensing circuit 10a and convert it into a digital signal with a sampling rate greater than or equal to 18 kHz. The analogue to digital converter 12 (ADC), converts the analogue signal measured by the first sensing circuit 10a into digital data. The analogue to digital converter can be, for example, a digitizer. As illustrated in FIG. 1C, the digital data is then provided to the controller 14 for processing.

The sampling rate for the first sensing circuit 10a is set using the analogue to digital converter 12. The analogue to digital converter comprises multiple channels, and each circuit 8a, 8b, 8c is connected to one of the multiple channels of the analogue to digital converter 12. In some embodiments a analogue to digital converter with 8 channels may be used, although it will be appreciated that this is merely an example and that a analogue to digital converter 12 may have a different number of input channels to those described herein.

Each channel may be set at a different sampling rate, and thus each sensing circuit 10a, 10b, 10c can be sampled at a different rate (if desired). In one example, the sampling rate per channel may be manually user selected. In another example, the apparatus 2 may be configured to determine the most appropriate sampling rate based on the electrical loads on each circuit 8a, 8b, 8c.

In other words, the sampling rate can be variable and/or set responsive to the loads on the circuit being monitored. The system may be configured to throttle down, for example when at 0 or near 0 power on a circuit and use a much lower sampling rate of for example 1 to 5 seconds. Alternatively, if the channel does not require the high sampling rate, a lower sampling rate may be used. The system may down sample a channel/circuit if not necessary on demand. This advantageously reduces the computational expense and power consumption of the monitoring unit or controller 14. The system may be configured to implement on demand throttling of the computational resource, with the full resources if required.

In some embodiments, a higher sampling rate may be used, for example, the sampling rate may be greater than about 0.5 MHz, or greater than about 1 MHz. In some embodiments, the sampling rate may be between 1 MHz and 5 MHz. A sampling frequency of greater than 1 MHz allows capture of the harmonics and transients in the signal, which is useful for being able to distinguish different electrical loads connected to the individual electrical circuits 8a, 8b. 8c. Particularly, as noted above, sampling rates at these levels allow different low-load devices of the same type to be distinguished from one another (e.g. such as two computer devices from the same manufacturer, that inherently have similar load profiles).

Briefly, the sensing circuit/sensor 10a samples the corresponding electrical circuit 8a at a high-frequency (typically 1-5 MHz, more preferably 1 to 2 MHz) and monitors variations in the sensed signals by an event occurring in that circuit 8a. As the power consumption of an electrical load changes, for example by being switched on or off, this generates a unique electrical signature within the electrical supply which is seen in changes in the sensed High-Frequency signal. By analysing this change in the sensed signal, each different electrical load can be identified as each has a different signature (load signature). This is described in greater detail in the appendix.

While the apparatus 2 of the present invention uses a high frequency sampling rate, as discussed above, the sampling rate itself can be variable (generally greater than 18 KHz, or between 1 MHz and 5 MHz in some embodiments). The sampling rate may be set dependent on various factors: the number of electrical loads connected to the first electrical circuit; the load characteristics of the electrical loads connected to the first electrical circuit; and/or the ambient temperature and/or humidity in the vicinity of the electrical loads. Thus, as described briefly above, the sampling rate for each channel of the analogue to digital converter 12 can be set dependent on the characteristics of the corresponding individual electrical circuit 8a, 8b, 8c, the temperature/humidity, the number and/or type(s) of loads connected thereto.

A complex load identification problem is likely to require a higher sampling rate/bit rate than simpler problems. For example, a circuit which comprises three light switches is not a complex problem and might only require a sampling rate of 1 hz and/or a low bit rate (the wattage amount for each light is distinct for each and so it is simple to attribute each step to one set of the lights). When there are many laptops which are variable loads on a circuit, it is more difficult to determine the load profile (and identify the appliances), especially determining the whole consumption profile of a specific laptop amongst identical units (i.e., several laptops of the same model). For such complex problems, a higher sampling rate is used.

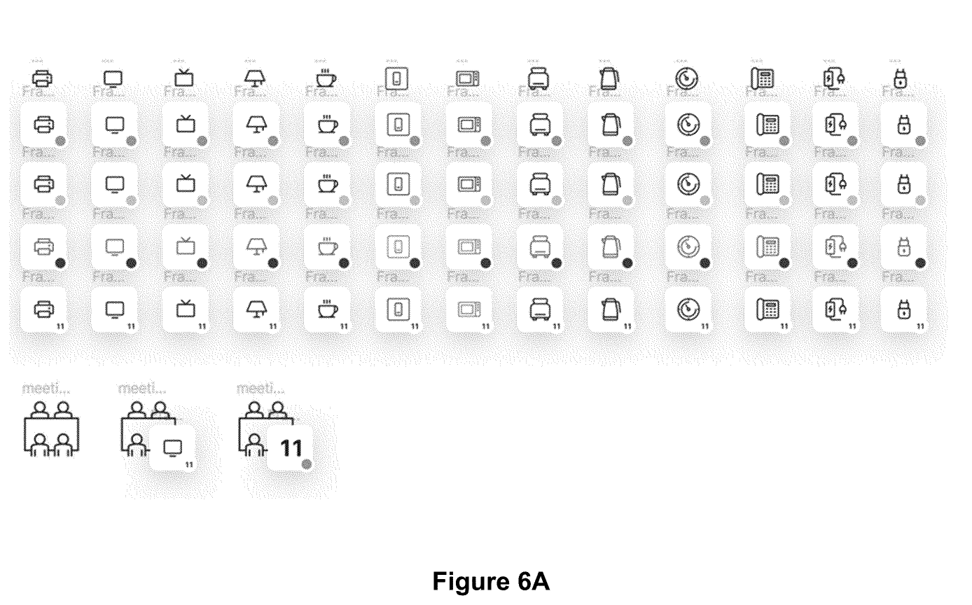

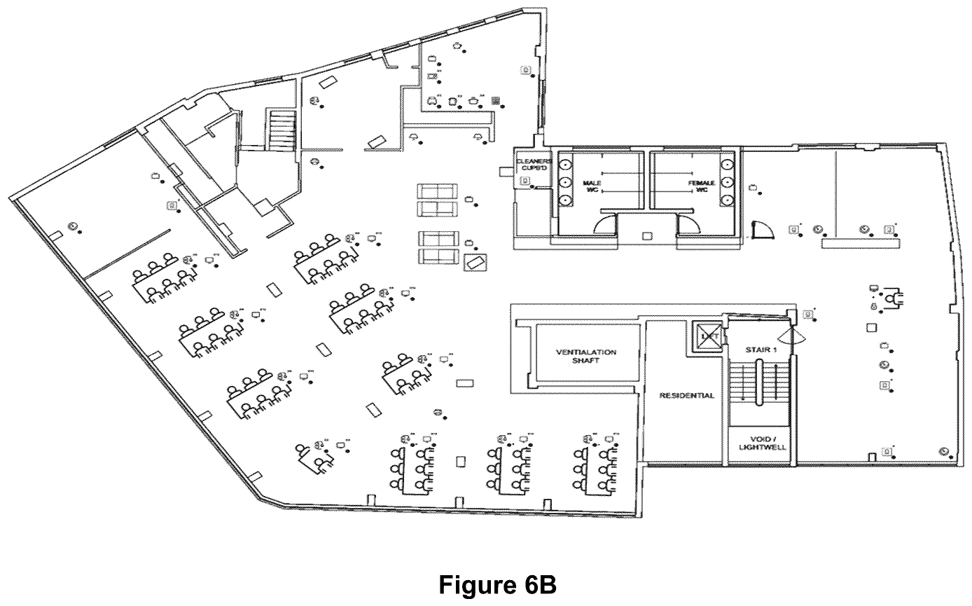

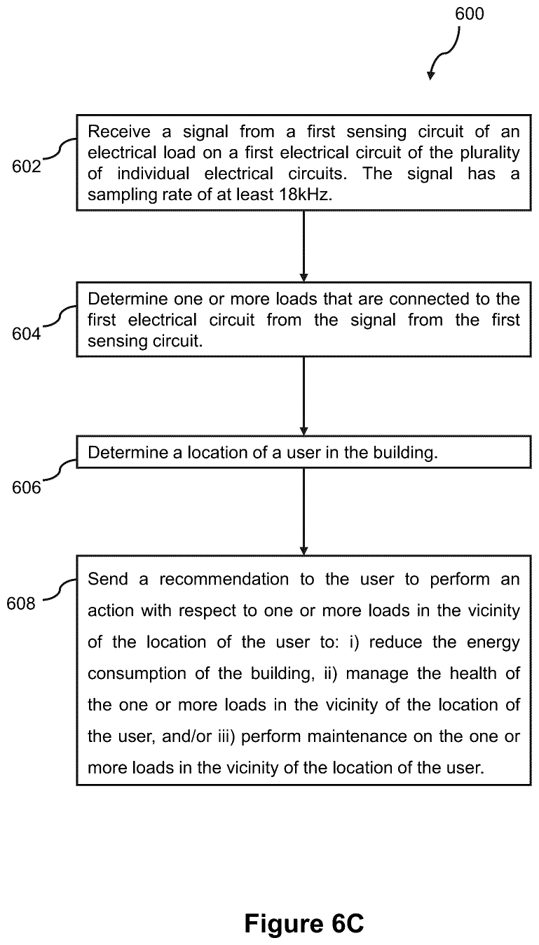

Considering the first electrical circuit 8a, which is connected to the first channel of the analogue to digital converter 12. The number of electrical loads connected to the first electrical circuit 8a may thus determine the sampling rate in the first channel. The sampling rate may be set to a higher rate when a first number of electrical loads are connected to the first electrical circuit 8a compared to when a second number of electrical loads are connected to the first electrical circuit 8a, wherein the first number of electrical loads is greater than the second number of electrical loads. In other words, the sampling rate may be set at a higher rate when there are more electrical loads connected to the electrical circuit. (The approximate number of loads may be determined from e.g. the icons plotted on a floor plan as illustrated in FIGS. 6A and 6B, and this information may be used to set the sampling rate In another example, the system may be configured to determine the most appropriate sampling rate based on the predicted load type determined using the load signatures measured, for example if no configuration (icon plotting) has been carried out.) A higher sampling rate is advantageous in such scenarios, as a higher resolution signal enables the different electrical loads to be picked apart or separated from one another.

Another factor that influences the sampling rate is electrical load type. The sampling rate may be set higher if there is more than one electrical load originating from the same type of device or appliance (e.g. same type of device, same manufacturer or similar) on the first electrical circuit 8a compared to if each electrical load on the first electrical circuit 8a is of a different type. In other words, the sampling rate can be set lower if each electrical load connected to the first electrical circuit is different. A high sampling rate can be helpful when there are multiple electrical loads of the same type connected to a first electrical circuit 8a as high frequency transients and harmonics in the signal can be used to distinguish between loads with similar signatures.

The sampling rate may also be set higher if one or more of the electrical loads connected to the first electrical circuit 8a is a low load electrical load compared to if the electrical loads are (all) high load electrical loads. This is because a higher sampling rate provides greater resolution with which to pick out the low-load signature.

Each component which sits inside electronics on a circuit board experience changes in resistance, capacitance, and/or inductance with changes in ambient temperature and, to a lesser extent, humidity.

A circuit board is made up of many components and will result in an electrical load having a unique load signature as a combination of component signatures. The load signatures of various electrical loads (i.e., for various components) can be recorded at different temperatures (and/or humidities) and stored in a database. The load signatures of each electrical load at different temperatures can then be accurately predicted, ensuring the load (e.g., appliance or device) can still be identified, even when the signature of the electrical load has been affected by temperature or humidity.

Turning now to the sensor(s), a circuit diagram of an electrical sensing circuit according to an embodiment of the present invention is provided in FIG. 2A. Here the inductive sensing is carried out using a Hall Sensor based circuit. In other embodiments different types of inducive sensors could be used. It is to be appreciated that other forms of metering sensors could be used in other embodiments. Generally, any metering sensor capable of determining resistive and/or inductive load characteristics from the sensed signals may be used. In the case of use of an inductive sensor, these characteristics (inductive or resistive), can be determined from analysis of the waveform produced by the inductive sensor. Also as has been mentioned before the design of any such new meter incorporating the sensing circuits described above is independent of the positional system and can provide benefit by disaggregating electrical loads on a circuit for analysis without the need for positional information being available.

A circuit diagram of the apparatus 2 according to another embodiment of the present invention is shown in FIG. 2B, where the first sensing circuit 10a comprises a coil. In this embodiment, the first sensing circuit 10a comprises a ferrite core 22 where one half of the ferrite core 22 is surrounded by a copper coil 24. The first sensing circuit 10a is connected in series with a variable resistor 26, which is in turn connected in series to the analogue to digital converter (ADC) 12. As outlined previously, the coil is configured to sense inductive load in the first electrical circuit 8a. The ferrite core 24 is used to ensure a consistent measurement. The analogue to digital converter 12 converts the sensed inductive load signal into a digital signal. The digital data is then provided to the controller 14 for analysis.

The variable resistor can be used to set the gain to avoid clipping, or conversely, not obtaining enough steps vertically from a weak signal.

In some embodiments, the apparatus 2 further comprises an auto gain adjuster. The auto gain adjuster is configured to automatically change the gain of the coil. When a high load electrical load is connected to the first electrical circuit 8a, the auto gain adjuster operates to limit the gain of the coil 24 in order to prevent damage to the input gate of the analogue to digital converter 12. When a low load electrical load is connected to the first electrical circuit 8a, the signal may be too low to measure, and so the auto gain adjuster operates to increase the gain of the coil 24. In other words, the auto gain adjuster is configured to select an appropriate dynamic range for the signal, enabling both low load and high load electrical loads connected to the first electrical circuit 8a to be measured. In such embodiments, the autogain adjuster may be placed between the current sensing coil and the analogue to digital converter, since the purpose is to modify the amplitude to keep in an optimal range for the analogue to digital converter.

As mentioned briefly above, the apparatus 2 may be further configured to output data indicative of the sensed inductive load and/or sensed resistive load to the controller 14. The data is provided to the controller 14 for processing, to determine the electrical loads connected to each circuit 8a, 8b, 8c. The controller 14 uses knowledge of resistive and inductive load signatures for given electrical loads to disaggregate electrical usage of different electrical loads on an electrical circuit 8a, 8b, 8c. Therefore, the apparatus 2 allows low power load detection, historical disaggregation of electrical loads on a circuit as well as map plotting and visualisation of electrical load usage.

In some embodiments, the apparatus 2 is configured to process a portion of the sensed inductive load and/or the sensed resistive load to reduce the number of samples therein before outputting the data to the controller 14. Essentially, to reduce the amount of data being sent to the controller 14, some of the processing is carried out by the apparatus 2 itself. In some embodiments, data may be processed at an edge circuit sensing device (edge processing) in the apparatus 2, such that a smaller set of pre-processed data is sent out of the building 4 to the controller (which may be in the cloud) 14. This reduces the computational complexity required to process the data. The variable sampling rate discussed above further reduces the computational expense and power consumption of the sensing hardware.

In some embodiments described herein, the high frequency signal is processed to determine one or more electrical loads connected to an individual electrical circuit of a plurality of electrical circuits. The high frequency signal may be the signal sensed by the systems described above and illustrated in FIGS. 1A to 1C. The data processing may be performed by a computer node.

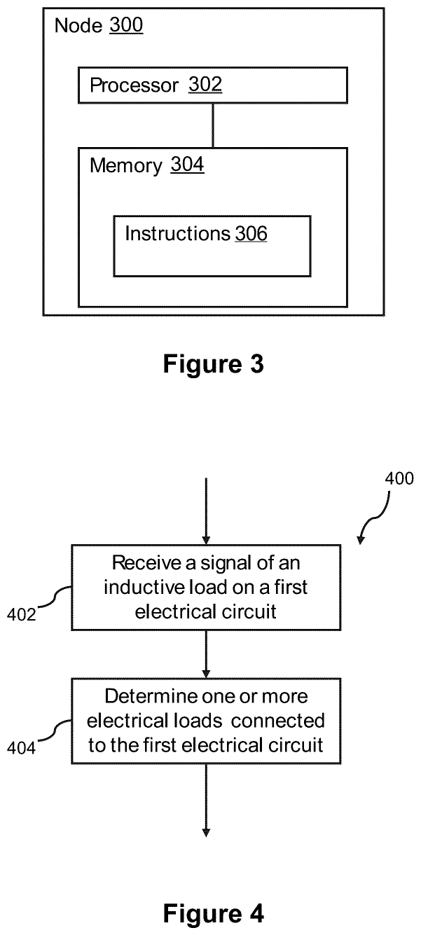

FIG. 3 shows a node 300 (e.g. a computing node) that may form part of some embodiments herein. The node 300 may, for example, be comprised in the controller 14 described above. A node 300 may generally be configured (e.g. operative) to perform any of the methods and functions described herein, such as the method 400 described below. Node 300 comprises a processor 302, a memory 304 and set of instructions 306. The memory holds instruction data (e.g. such as compiled code) representing the set of instructions 306. The processor 302 is configured to communicate with the memory and to execute the set of instructions. The set of instructions, when executed by the processor, may cause the processor to perform any of the methods herein, such as the method 400 described below.

Processor (e.g. processing circuitry or logic) 302 may be any type of processor, such as, for example, a central processing unit (CPU), a Graphics Processing Unit (GPU), a Neural Processing Unit (NPU), or any other type of processing unit. Processor 302 may comprise one or more sub-processors, processing units, multi-core processors or modules that are configured to work together in a distributed manner to control the node in the manner described herein.

The node 300 may comprise a memory 304. In some embodiments, the memory 304 of the node 200 can be configured to store program code or instructions that can be executed by the processor 302 of the node 300 to perform the functionality described herein. The memory 304 of the node 300, may be configured to store any data or information referred to herein, such as for example, requests, resources, information, data, signals, or similar that are described herein. The processor 302 of the node 300 may be configured to control the memory 304 of the node 300 to store such information. In some embodiments, the node 300 may be a virtual node, e.g. such as a virtual machine or any other containerised computer node. In such embodiments, the processor 302 and the memory 304 may be portions of larger processing and memory resources respectively.

It will be appreciated that a computing node 300 may comprise other components to those illustrated in FIG. 3. For example, node 300 may comprise a power supply (e.g. mains or battery power supply). The node 300 may further comprise a wireless transmitter and/or wireless receiver to communicate wirelessly with other computing nodes and/or hardware or infrastructure, such as the analogue to digital converter 12, a bluetooth beacon or scanner, or a temperature or humidity sensor as described above. In some embodiments, the node 300 may have a wired connection with which to communicate with other computing nodes, hardware and/or infrastructure.

Turning to FIG. 4, FIG. 4 is a flowchart showing a method 400 for monitoring electrical load in a building. The method 400 may be performed by the node 300 (or the controller 14, or the data processing manager of FIG. 1B) described above. The method may equally be performed by a computer program, such as a computer application (“app”).

As noted above, the building has a primary electricity supply (e.g. a mains power supply) that is split into a plurality of individual electrical circuits (e.g. via one or more electrical consumer units). Briefly, the method comprises, in a first step, receiving 402 a signal from a first sensing circuit of an inductive load on a first electrical circuit of the plurality of individual electrical circuits, wherein the signal has a sampling rate of at least 18 kHz. In a second step, the method comprises determining 404 (e.g. identifying) one or more appliances connected to the first electrical circuit, from the signal from the first sensing circuit.

As described previously, an electrical load is any component (e.g. an electrical appliance or device) that consumes electrical energy. A building has a primary (main) power supply. The primary power supply splits (separates) into a plurality of individual electrical circuits. Each individual electrical circuit connects to and supplies electricity to one or more electrical loads.

In more detail, the method firstly comprises receiving 402 a signal from a first sensing circuit of an electrical load on a first electrical circuit of the plurality of individual electrical circuits, wherein the signal has a sampling rate of at least 18 kHz. In other words, the method comprises receiving a high frequency signal comprising data on the electrical load sensed (measured) at an individual electrical circuit (e.g. first circuit 8a, or circuits 8b, 8c) in the building. The signal may be received from the apparatus 2, or from the sensing circuits, both of which are described previously. The signal has a sampling rate of at least 18 kHz. This is higher than sampling rates typically used in electrical load monitoring in buildings. In some embodiments the signal has a sampling rate of between about 1 MHz and about 5 MHz. The high frequency signal allows for distinguishing different electrical loads on the individual electrical circuit, as is described in greater detail later.

In some embodiments, where the first sensing circuit comprises a coil (e.g. as in FIGS. 2A and 2B described above), the first sensing circuit detects current fluctuations and the coil is used for current sensing. The signal received in such embodiments is the current waveform being drawn by the loads connected to the first circuit.

In some embodiments, the voltage waveform is also obtained. For voltage sensing, two approaches can be used. In a first approach, Voltage Transformers (VTs) are used: Similar to CTs, VTs reduce the high voltage from the mains supply to a safer, lower voltage that can be measured by the NILM device. They ensure electrical isolation and protect the device from damage.

In a second approach, Resistive Voltage Dividers are used: These simple circuits use resistors to divide the voltage proportionally, making it easier to measure. They are often used in combination with voltage transformers to further reduce the voltage to a level suitable for analog-to-digital conversion.

As such, in some embodiments, the first sensing circuit may detect voltage fluctuations (e.g. the voltage waveform). The first approach, the second approach, or any other suitable sensor set up may equally be used.

In some embodiments, the first sensing circuit may sense the current waveform and a second sensing circuit may sense the voltage waveform.

Returning to FIG. 4, in a second step, the method 400 comprises determining 404 one or more electrical loads connected to the first electrical circuit, based on the signal from the first sensing circuit. In other words, the method comprises determining (e.g. identifying) which loads (appliances, devices) are connected to one of the individual electrical circuits (e.g. first circuit 8a) of the plurality of electrical circuits in the building. For example, in step 404, the number of electrical loads connected to the circuit may be determined, and/or the type (e.g. nature) of each lead may be identified. For example, the method may determine that there are 6 printers and two televisions connected to an individual electrical circuit 8a.

In some embodiments, the step of determining 404 comprises determining one or more electrical loads on the first electrical circuit based on load signatures in the received signal using mixed deep learning models, Fast Fourier Transform (FFT) and/or techniques related to Nonintrusive Load Monitoring (NILM). As noted above, a load signature corresponds to a change in electrical load on the first electrical circuit when an appliance is activated.

In more detail, the power consumption of an electrical load connected to an electrical circuit changing (e.g., being switched on or off), causes a unique electrical signature in the individual electrical circuit (e.g. circuit 8a). The change in the electrical signature (e.g. first circuit 8a) is seen in the high frequency signal sensed by the corresponding sensor circuit (e.g. first sensing circuit 10a). Each electrical load has a different signature. Individual signatures in the sensed signal can be separated using various complex data processing techniques, such as those outlined above. Once separated, the individual load signatures can be used to determine the electrical load type.

The individual load signatures can be separated using techniques such as non-intrusive load monitoring methods that will generally be familiar to the skilled person. Some of these techniques are described in the paper by Azad et al. (2023) entitled: “Non-Intrusive Load Monitoring (NILM) using Deep Neural Networks: A Review”; arXiv:2306.05017.

NILM approaches recognize the difference between inductive and resistive loads primarily by analyzing the relationship between voltage and current waveforms. Resistive Loads: In purely resistive loads (like incandescent light bulbs or heaters), the voltage and current waveforms are perfectly in sync. This means they reach their peak and zero values at the same time. Inductive Loads: In inductive loads (like motors or transformers), the current waveform lags behind the voltage waveform. This lag is caused by the energy stored in the magnetic field of the inductor. Phase angle differences between voltage and current can help identify reactive power components, which are essential for distinguishing between appliances with similar power consumption but different reactive power characteristics.

In some embodiments step 404 is performed using a model trained using a machine learning process to determine (e.g. identify or classify) the one or more electrical loads from the signal from the first sensing circuit. It is possible to use machine learning in this way due to the high frequency and circuit-level sampling described above.

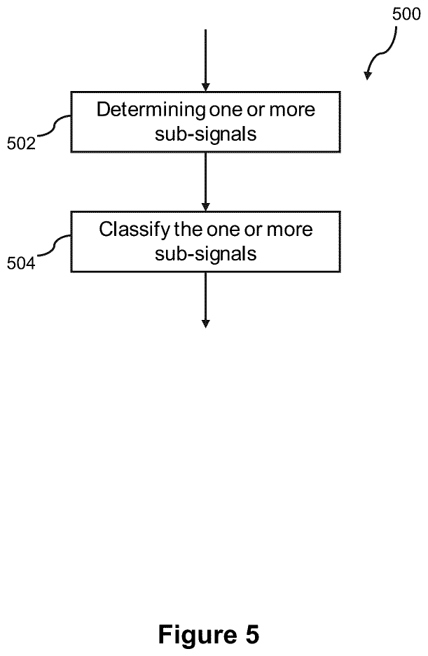

As illustrated in FIG. 5, the signal from the first sensing circuit may be separated 502 into sub-signals, each sub-signal corresponding to a different load on the first circuit. In other words, the signal from the first sensing circuit may be decomposed into the individual components. Each sub-signal may then be classified 504 according to load-type. In this way the loads on a circuit can be identified.

The skilled person will be familiar with machine learning and machine learning models, and will further appreciate that a wide range of different configurations, and/or combinations of models may be used to separate the load signals from the circuit-level load data, and/or to subsequently classify them. It will further be appreciated that if enough data is available or training, that a single model (e.g. such as a neural network) may be trained to take an entire load signature and output the loads in said signal (e.g. a single model may be able to predict the loads from the signal from the analogue to digital converter 12).

As an example, in step 504, unsupervised machine learning models may be used to group different load signatures (e.g. sub-signals) into clusters, each cluster corresponding to a particular device type. This may be performed using methods such as K-means clustering. In such embodiments, a user only needs to label an individual sub signal in the cluster, and the rest of the devices in the cluster may be labelled with the same label. This is based on the same types of devices having common load characteristics.

As another example, in step 504, a neural network may be trained to take a load signature as input and to classify as a particular type of load (e.g. as a particular type of device, appliance or system).

The skilled person will be familiar with machine learning and methods of training a model using a machine learning process. Briefly, a model, which may otherwise be referred to as a machine learning model may comprise a set of rules or (mathematical) functions that can be used to perform a task related to data input to the model. Models may be taught to perform a wide variety of tasks on input data, examples including but not limited to: determining a label for the input data, performing a transformation on the input data, making a prediction or estimation of one or more parameter values based the input data, or producing any other type of information that might be determined from the input data. The model then provides the label/transformation/prediction etc as output.

The skilled person will be familiar with methods of training e.g. neural networks. For example, there are a range of open-source code libraries that can be used. Examples include: TensorFlow, the code of which is available here: TensorFlow Developers. (2024). TensorFlow (v2.15.1). Zenodo. https://doi.org/10.5281/zenodo.10798587 See also the paper: Martin Abadi et al. TensorFlow: Large-scale machine learning on heterogeneous systems, 2015. Software available from tensorflow.org.

Another example of a suitable open-source model is “Scikit learn” described in the paper: Scikit-learn: Machine Learning in Python, Pedregosa et al., JMLR 12, pp. 2825-2830, 2011.

A model may be trained using the training data described above, based on the training principles and default starting conditions described in the respective training manuals.

Various open-source training data sets may also be used to train the models herein, such as: UK DALE described in the paper by Kelly & Knottenbelt entitled: “The UK-DALE dataset, domestic appliance-level electricity demand and whole-house demand from five UK homes”, arXiv:1404.0284.

BLONDE, described in: Kriechbaumer T, Jacobsen H A. BLOND, a building-level office environment dataset of typical electrical appliances. Sci Data. 2018 Mar. 27; 5:180048. doi: 10.1038/sdata.2018.48. PMID: 29583141; PMCID: PMC5870472.

COOLL: arXiv:1611.05803 COOLL: Controlled On/Off Loads Library, a Public Dataset of High-Sampled Electrical Signals for Appliance Identification by Picon et al. HFED (which is around 5 MHz). See: “An In Depth Study into Using EMI Signatures for Appliance Identification” Authors: Manoj Gulati, Shobha Sundar Ram, Amarjeet Singh. Proceedings of the First ACM International Conference on Embedded Systems For Energy-Efficient Buildings (2024).

As an example, in some embodiments, a single neural network model may be trained to perform the feature extraction and the classification. For example, a spectrogram based approach may be employed, which involves processing the waveforms into spectrograms and then feeding the spectrograms to the model for processing.

In some embodiments, the training may use an active learning approach, that makes use of user appliance tagging to validate the appliance category. It will be appreciated that these are merely examples however and that other methods may equally be used.

In some embodiments, the model may classify the one or more sub-signals based on transients and harmonics in the one or more sub-signals. The detection of transients and harmonics, particularly of low-load devices where there is a mix of low and high-loads on the first circuit is made possible because of the high sampling rates herein. Classifying using transients and harmonics allows electrical loads of the same type to be distinguished from one another. For example, two different printers connected to the same electrical circuit can be distinguished from one another. The signal from the first sensing circuit as captured using the systems described above with respect to FIGS. 1 and 2 is of sufficient sampling frequency to capture the harmonics and transients, thus facilitating such classification methods.

In some embodiments, in addition to the load signature, the model further takes as input data relating to an electrical load age, temperature, humidity and/or other environmental conditions. These characteristics may assist the model in classifying the electrical loads, as electrical loads may be affected by the above-listed factors. For example, an older appliance may have a different electrical signature compared to a new appliance. Thus, in some instances, it may be difficult to classify a sub-signal according to electrical load type, particularly when an electrical circuit connects several different electrical loads that are affected by age and temperature. Thus, providing factors such as age (and environmental conditions) as an input to the model 500 may help the model 500 to classify electrical loads, particularly electrical loads of the same type.

Thus, data relating to component and/or appliance age, temperature, humidity and other environmental conditions, and how this affects load signature, may be used to train a machine learning model, which is then used to predict the load signature for a particular appliance.

The output of the model may be any information related to the load or load(s) on the first electrical circuit. For example, the model may identify or detect each load instance (e.g. each appliance or device on the first electrical circuit). The model may classify each load instance e.g. according to type. Furthermore, the model may provide as output one or more electrical characteristics, such as the live wattage of each detected load. It will be appreciated that these are merely examples of possible outputs that a model may be trained to provide and that other outputs are equally possible alternatively or in addition to those described above. As another example, the model may output a fault parameter, diagnostic parameter or other information related to maintenance of the load, as described below.

In some embodiments, if the model is unable to classify a sub-signal, or is unable to identify the load corresponding to the sub-signal with sufficient accuracy or confidence, a user may be asked to identify said sub-signal. This may be performed by sending a message to the user, e.g. via an app on the user's device. As such, the method 600 can further comprise determining an unknown sub-signal in the signal and sending a request for a user to supply a first user input identifying an electrical load associated with the unknown sub-signal. An unknown sub-signal is a sub-signal that the model is unable to classify according to electrical load type. The method May separate (isolate) the input 502 (inductive load signal) into a plurality of sub-signals, then be unable to classify one or more of the sub-signals. In such instances, the method comprises sending a request to (asking) the user to identify the electrical load.

The request may comprise information that allows the user to identify the electrical load for the unknown sub-signal. For example, the request may state that on a particular electric circuit there are 4 electrical loads (appliances) and provide the electrical load type for 3 out of 4 of the electrical loads. The information can be used by the user to identify the final electrical load. The user may supply (provide) a user input that labels the unidentified electrical load. The user input may comprise an interaction with the system (e.g. input into an app).

In some embodiments, the label and the unknown sub-signal can be used as further training data with which to further train the model. In other words, the label provided by the user for the unknown sub-signal is used to train the model 500.

The system may further be configured to determine whether an appliance has broken by an anomalous shutdown load signature upon the appliance breaking (e.g., due to a short circuit or burned-out components). For example, a burned-out capacitor will likely discharge quickly, sometimes with a spike before, rather than slowly and steadily as one would expect a functioning capacitor to. The system may comprise an anomaly detection module configured to detect such anomalies. Appliances with anomalous load signatures may be categorised as broken. The anomaly detection module may measure anomalous, or specific features of a load's signature upon shutdown. Alternatively or additionally, the system may be configured to detect anomalous characteristics of a load and label it as faulty.

Furthermore, older appliances may have a different signature than newer appliances. The relationship between appliance and/or component age and load signature may be monitored and plotted in a graph to be able to extrapolate the load signature for appliances of different ages. In one test example, the load signature of a new power supply is measured, for example an AC to DC power supply such as a switched mode power supply (SMPS) power brick for a laptop. The load signature of capacitors of a new power supply are replaced with old capacitors, and the load signature of the appliance is also measured. It is then possible to compare how the age of the capacitors affects the load signature of the same power supply. The change in load signature over time is measured and plotted in a graph. It is then possible to extrapolate from the graph and predict how aging will affect the signature.

In some embodiments herein, the classified load signatures can be matched to particular locations in the building. In other words, the physical location of each load can be determined or identified. This can be performed in different ways. For example, in some embodiments, the location of each load may be identified from acoustic signatures (e.g. sounds) recorded within the building. For example, if it is known that the first electrical circuit supplies electricity to appliances or devices in a first location, e.g. such as a particular floor of the building, then the sounds recorded on said floor of the building can be used to determine the physical locations of the loads detected on the first circuit. As such, the method 400 may further comprise, in a first step, obtaining acoustic signatures in the physical vicinity of the first circuit; and predicting locations of the one or more appliances in the building, based on the acoustic signatures. The acoustic signatures may be received from sensors in the building, or via other means, e.g. for example using mobile device data from mobile devices (e.g. such as mobile phones, tablets etc) of users in the building.

In some embodiments, the method 400 may further comprise obtaining mobile device data of a user in the physical vicinity of the first circuit. The method may then comprise predicting locations of the one or more electrical loads in the building, based on the mobile device data. In other words, data provided from a mobile device may be used as an input and used to determine a location of a particular electrical load (appliance, device) in a building. Thus, if a printer is identified on the first circuit, and a sound detected by a first user device, at a first location in the physical vicinity of the first circuit, is identified as corresponding to a printer, then said printer may be linked to the first location.

Regarding the mobile device data, a mobile device is able to provide many types of data. In some embodiments, the mobile device data obtained comprises: data identifying a location of the mobile device, for example a wifi triangulation of the location; Global Satellite Positioning, GPS, data of the mobile device; one or more images captured by the mobile device; and/or acoustic data captured by the mobile device. Each of these data types is useful for predicting a location of an electrical load.

To help establish where a specific electrical load is, the system can display a map of the area in which the user is located (previously uploaded to the system) and provide a user interface for the user to populate that map with icons (FIG. 6A) indicating the locations of interaction points (touchpoints) of electrical loads consuming power. These icons also indicate the status of the electrical load on/off/standby (phantom load) using colours for example red for off, yellow for phantom load and green for full operation. This population of the map (for example as shown in FIG. 6B) enables the system to know the location of any device within the monitoring environment and this can also be made known to the user via the app operating on their smartphone. The system can then highlight devices on the map which need to be switched off. This map may be considered to be a live digital model of the electrical circuits and loads of a building.

By being able to track movement of users (via their mobile devices) and by knowing the location of electrical loads in the building and when those devices are turned on, the system knows which user turned on or off a device at a given moment in time. This advantageously enables the system to attribute actions which have a material effect on energy consumption to individual users. This then enables the specific feedback mentioned above to be provided to that specific user regarding their energy consumption behaviour. Also, the system can remind specific users to turn off specific devices at an appropriate time. For example, if the user is the last person leaving an office, the system will know this as there are no other mobile devices detected by the beacons in the office, the system can send a push message reminding that user to switch off the lights or appliances. Similarly, the system can notify a user if an appliance is on but there is no one in the vicinity of the appliance, for example if lights are turned on in a room but no one is present (possibly after a predetermined time period has elapsed).

Different techniques may be used to determine the location of users' personal devices, and in turn, the location of users. As noted above, such techniques include but are not limited to Global Positioning System (GPS), Wi-Fi and Bluetooth.

Using Wi-Fi to determine the location of users is advantageous because it is possible to use existing infrastructure (e.g., Wi-Fi access points and routers etc). Wi-Fi based location identification may consume significant power of a personal device, but the system may be configured to reduce power consumption by not reading the user location when a user is not moving or reducing the number of times it reads the user location. Wi-Fi may be used to determine users' location by sensing the signal strength of the personal device to an access point (e.g., to determine an area a user is located in) or multiple access points (to determine a more precise position of the user). In one example, Wi-Fi signal will be of a particular strength for a user a first distance radially from a first access point and another strength for the user a second radial distance from a second access point etc. The location of the user can be determined based on where these radial distances overlap. In other examples, trilateration or multilateration may be used to determine the position of users.

Other ways of localising a user's position using Wi-Fi include Wi-Fi fingerprinting, angle of arrival, and time of flight methods. The user may be connected to a Wi-Fi access point for their location to be determined using these techniques.

Radar-based methods for indoor positioning may also be used. For example, using multiple ultra-wide band (UWB) radar nodes, the position of an object (or person) can be determined through multilateration.

In another example, Bluetooth Low Energy (BLE) with angle of arrival (AoA) capability may be used to determine the location of users in a building.

The system may additionally combine other pre-existing sensors of the user's personal device, such as an accelerometer and compass, to increase the accuracy of the Wi-Fi indoor positioning.

As discussed above, icons may be dragged onto a building model (map). Dragging and dropping the icons for access points/routers (or Bluetooth beacons and/or anchors) on the floorplate enables indoor positioning without additional hardware. Based on where each icon is dragged to on the building model, the system determines the locations to provide the trilateration/triangulation of personal devices. The system May further have passive elements, for example, by requiring a user to leave a personal device (e.g., phone) or tag on their person while in the building.

The known IP address of the access point/router may also be applied to icons on a building map (e.g. as in FIGS. 6A and 6B).

The icons may be geofenced, and there may also be assigned geofenced areas. Icons may be geofences (a virtual perimeter for the real-world geographic area corresponding to the icon) or geofenced areas may be set in a similar manner as how the out of limits area is set for the bathroom. For example, the location of the stairs or cycle storage may be a geofenced area. An example building model with the bathrooms, lift and stairs geofenced is shown in FIG. 11.

If a user is determined to be in a location which corresponds to the geofenced lift area or geofenced stair area, the system can determine that the user has taken the lift or stairs respectively. Similarly, if a user is determined to be in a location which corresponds to the geofenced bicycle storage area, the system may determine the user has cycled to work. Rewards may only be allocated to the user if users are determined to be in a particular area at a certain time (e.g., in a bicycle storage unit between 5 and 10 AM), for example as this is more likely to indicate that the user has cycled to work, rather than a user merely visiting the bicycle storage unit.

How often the location of the user is updated may be reduced to reduce personal device power consumption.

In some embodiments, the method may further comprise providing a suggestion/recommendation to the user of an action that could be taken by the user to reduce the energy consumption of the first electrical circuit and/or to manage the health of the one or more loads in the vicinity of the location of the user, by matching the locations of the one or more appliances to a location of the user. In other words, the method may comprise providing feedback to the user, suggesting that they carry out a task to reduce energy consumption/manage the health of the loads on the circuit. For example, the suggestion be to turn off may a light. In some embodiments herein, the heath of the electrical loads (devices/appliances etc) on the first circuit are monitored and recommendations are made to users to improve or manage the health of said electrical loads. For example, as noted above, the way that current is drawn by a load can be used as an indicator of health. For example, older or less efficient devices care associated with lower efficiency and noisy electrical signals (which can be determined using e.g. the clustering methods above, whereby loads of the same type but in different regions of the cluster may be associated with older or inefficient devices). Furthermore, device health and/or aging of devices may be monitored by looking at the changes in the load signatures over time.

The systems described herein can pick up early-fault detection due to their ability to sample the current waveforms at such high sampling rates. This allows the system to capture startup-transient behaviour of the appliances which low-sampling devices fail to capture. Inrush current and switching transients (on and off of internal components) can be picked up by the hardware which reveal information about the health of switches, relays and other components within consumer appliances. Most importantly, due to the high sampling rate, the system is capable of picking up unique noise signature of the appliances. Damaged or malfunctioning components can generate electrical noise or other changes in the in the appliance's signature or waveform, which can be detected to perform accurate fault detection.

More generally there is a method of detecting a fault, damage or malfunction in an appliance or device by using a NILM to detect a waveform or signature of the appliance or device, monitoring said waveform or signature over time, and detecting a change in waveform or signature over time. Such changes can be flagged to a user to indicate potential damage. Changes in a waveform include but are not limited to: increased noise of signal, a change in amplitude or voltage, or any other change in the waveform over time. It will be appreciated that the method described in this paragraph may be performed on the signals/waveforms described herein or on waveforms obtained using any other type of equipment to that described herein.

Such methods can be very useful in e.g. care homes or hospitals, for, for example, the fault detection and predictive maintenance of complex medical equipment such as MRI machines. Detecting faults in machines could save lives. In care homes, the systems may be used to model human behaviour for correct treatment, and response, and to provide an early warning system of increase security/hazards.

Thus, faults, damage and other malfunctions may be detected via the load signatures of the individual loads and a recommender system may be used to make recommendations related to e.g. maintenance e.g. as a result of fault detection of a device connected to the first circuit.

In one non-limiting embodiment, the IoT system utilizes a cloud provider to store data.

The system in this non-limiting embodiment employs three machine learning models for Device Identification, User Location, and Recommendations, and could in one embodiment use Amazon SageMaker. IoT devices communicate with the system via MQTTs protocol, and the data is stored in a large data store such as an Amazon S3 data lake.

Abilities of the system include:
Determining the position of the user (user's phone), with accuracy sufficient to the use-case.
Generate recommendations for users to save electricity (or electricity costs).
Identification of connected devices based on waveform signature.
Loading room plans and determining in which places which devices are placed in an easy to use for both software and hardware. This not only reduces set up time but allows for the installation to be relatively unskilled.
Monitoring of the current status of the connected load in near real time.
Motivate users to take energy saving actions (Reward system).
Track the actual implementation of user recommendations through close to real-time monitoring.

The system may calculate statistics about energy consumption and timing and use those statistics in shaping their recommendation for the users. Also, the system is configured to generate information which can be useful to controlling the energy consumption of that building. For example, the system of the present disclosure can determine:
anonymous occupancy/space utilisation insights
how many people are in the building and at what time
what is the busiest day/time period
heatmaps of occupancy on any given day
a weekday view heatmap
the number of people in the building at one time; and
historical information

The user can also get real-time visualisations of consumption of each appliance or device to show which appliances consume the most energy. Also, the user can get push notifications reminding them to turn off appliances in difference situations, for example if they are exiting a building or an appliance has turned on, but no one is in the vicinity of that appliance. The map (e.g. as shown in FIGS. 6A and 6B) can also show areas of busiest traffic (concentration of user movement at locations within the building). For example, in an office building a floor plan can be provided, the location of energy consuming devices can be shown as well as the locations of the beacons, other sensors and touchpoints. The unique identification of users and their actions in relation to energy consumption enables the system to issue rewards (such as points) to individuals for their specific energy saving behaviour. That behaviour is determined by monitoring changes in patterns of energy consumption and attributing those changes to the tracked locations of uniquely identified users via their portable mobile devices such as smart phones. The changes in energy consumption are attributable to turning on or off an electrical device. These rewards may even by monetary in value.

The suggestion (feedback) to users can be in different ways. For example, the system may provide users some facts. Facts can be interesting and catching. For example: ‘Shutdown computer after use each day instead of leaving on standby’. This is not individualised, and points (as a form of reward) are given to everyone. Users also can get recommendations based on statistics in their office. Some of these recommendations can be provided immediately (such as how to play a mini game to reduce consumption), others are provided after a period of monitoring once the system has enough data to analyse and create customised recommendations for the user. These recommendations can be accepted or ignored, and the system can track this response to the fact/recommendation. Points can be awarded once a user has proved that they have carried out energy saving actions. More specifically, points are Individual points are awarded where the system records that a user has turned off a specific touchpoint because of their proximity to that touchpoint and the successful recognition. Points can generally be awarded based on factors such as how close they are to a touchpoint. Or creation of a geofence around the touchpoint. These can change by the accuracy tier level based on hardware and configuration steps achieved. This can help compensate for a potential inaccurate indoor positioning system.

Communal points are awarded if the system is unable to individualise the behaviour because: the user is not registered on the system, the user's mobile device (phone) is off/disconnected, or due to normal inaccuracies in device deduction (inability to deduce due to noise perhaps (maybe 10-20% of the time). In these situations, the points are split evenly amongst all users. The system may further be configured to reward groups of people as well as individuals. In one example, the system may attempt to reward individuals for energy saving behaviour but if it is not possible to distinguish between individuals (for example due to two people being detected very close to each other near an appliance which has just been switched off) then groups of individuals may be rewarded (e.g., both individuals detected close to the appliance switched off or a team of individuals). In another example, if an individual belonging to a particular group displays energy saving behaviour, the group they belong to may be rewarded (e.g. the Human Resources team etc.).

The reward can be a cryptocurrency. This is because the system is measuring actual energy consumption, which is non-abstract, the points system can be very logical.

In order to distribute the individualised or communal rewards as accurately as possible, a rewards module of the system has its own logic or algorithm which takes into account:
Individual load total event kwh factors vs past periods individual or communal.
The magnitude or weighting of each action based on the energy saving potential of the appliance or action. E.g. turning off a phantom load will likely not give as many points as a light, but it depends on how long the appliance's off state is recorded.
Rules which prevent points from being tallied for repeated on/off of a switch. One way this is achieved is by summing up points after the appliance is next turned on or by statistics based on set periods.
A way of effectively measuring or quantifying a saving amount without having to relate back to a past year period.

Furthermore, such high fidelity of electrical power consumption enables a system to implement mini games with users to help reduce electrical power consumption. Even some degree of individualisation is possible through timer-based mini games as the internal clocks would sync. It is to be appreciated that this meter does not rely on the positional information of the user in order to operate or provide a technical benefit, namely a much higher degree of resolution and disaggregation than has been possible before in meters.

In order to associate a user with an event, it is necessary for the system to know the locations of touchpoints within the monitoring space. This is achieved in a set-up procedure where typically a map or floor plan of the monitoring environment is uploaded to the system and manually populated with touchpoint icons. Each touchpoint icon represents an electrical load on the system and by moving it to a particular position on the map of the monitoring environment, the physical location of the touchpoint is established for use in comparison with user position data received from the position sensors in FIG. 1A. Examples of different icons for different appliances are provided in FIG. 2A. Also, an example of a floorplan map populated with such icons is shown in FIG. 2B and a user interface (UI) which can be generated by the system to provide analytical results of electrical usage over time is shown together with the floor plan in FIG. 2C.

Each icon can also have certain rules or instructions. For example, a kettle icon can have associated with it a specific kettle mini game. In this example, the user can be provided with guidance (recommendations) and then verification that the guidance had been followed through the tracking or footprinting of how that kettle is being used. The user variable is how much water is put into the kettle. This directly affects the time that the kettle takes to boil which in turn directly reflects the energy consumption associated with the event of switching on a kettle. Boiling a kettle slightly less full (as only one cup is required) or for less time (manually switching it off before it boils) can be associated with a positive energy saving behaviour and so if this behaviour is detected the user can be rewarded in the minigame. In other words, the system can be used to modify user behaviour which in turn can lead to benefits such as reducing the total electrical consumption amount per event or increasing the total amount of physical activity per event.

The map, or floorplate model shown in FIGS. 6A and 6B serves many functions. Using the map, the system enables easy configuration of the hardware/software and provides a step-by-step positioning of the IPS (Indoor Positioning System). In use, the sensing circuit is installed by electrician within an hour, the manager/installer uploads the floorplan of the monitoring environment and the then positions the appropriate icons on the map to effectively create a model of the monitoring environment (which may only take a few minutes).

In order to configure the system, a technique referred to as Appliance Tagging can be carried out. Appliance Tagging involves determining a baseload picture setting in the software with all electrical loads (appliances) preferably in the monitored region but at least on a given circuit, being switched off. Then a single appliance is turned on and the change to the sensed current and voltage in the electrical supply is recorded. This generates a signature for that appliance which is then associated with an icon representing that appliance. The icon representing the touch point of that appliance has already been positioned on a map of the monitored area such that its location within the monitored area is determined. This is important as user interaction with that touchpoint of the appliance is detected when the position of the user coincides with the location of the touchpoint and an event occurs relating to the power consumption of the appliance relating to that touchpoint as detected by sensing an electrical load signature.

As mentioned above, the locations where the user can interact with an appliance or any electrical load bearing device, is called a touchpoint. Note that this may not be the actual location of the device as it may be operated by a remote control or have a control interface positioned remotely from the appliance such as a heater and a control thermostat or a television and a remote control for that television. Other examples of touchpoints include a master power off switch on the side of a commercial printer, a device shut off internally through software like laptop shutdown, or even a wall plug switch, lamp switch etc.

In one non-limiting embodiment, steps for implementation Appliance Tagging are:
1. Turn everything off on the circuit.
2. Drag icon onto building model (map)
3. Turn on that appliance on. (System registers that load signature and attributes to icon which has dataset)
4. Turn that appliance off
5. Repeat process for all touch points (icons)

In this embodiment, multiple position sensors (beacons) are provided throughout the monitoring environment which interact with user devices such as smart phones to determine user location. These interactions are typically via wireless sensors such as Bluetooth sensors. However, in other embodiments, other types of wireless positioning sensors can be used, such as infra-red sensors or Lidar sensors. In the present embodiment, the strength of signal can be used to determine the distance from each sensor (beacon) and triangulation techniques using at least three sensors can be used to determine exact location. The user location data can be passed onto the InfraMesh backend system for processing, though in this embodiment much of the user location processing is carried out locally, for example by use of edge processing. Multiple users can be tracked within an environment simultaneously. In other embodiments, it is possible to use other techniques for location determining. For example, it is possible to use angle of arrival of signals at a sensor (for example when using Bluetooth), trilateration techniques or a combination of any of the above-described techniques for determining device location within the monitoring environment.

Thus, embodiments herein are directed to the way occupants (users of any electrical load bearing devices) manage property by leveraging the power of AI and IoT. The solutions herein have the potential to transform the way building occupants make money and businesses save money and improve the energy efficiency of buildings.

The solution can be split into two user interaction parts: a Management platform for Managers and an Occupant app for Employees which runs on their respective smartphones.

For occupants, such as employees, who want to earn extra money and be more eco-friendly, the present system is meant to raise awareness of the amount of energy consumption in a particular building or a location in a building (such as a floor of the building) and provide an opportunity to receive rewards for switching off different electrical appliances which helps to reduce electricity consumption. The present system can also alter user behaviour which can lead to a reduction in a user's carbon footprint or an improvement in the user's health. For example, reducing the need for a user to commute into an office, or increasing the amount of physical activity that the user is undertaking as monitored by a fitness tracker such as Strava and its analysis as could be undertaken by Whoop. More specifically, the system could prompt the user to turn off a plurality of appliances which directly causes the user to undertake some physical activity to undertake that task.

For managers who want to reduce costs on electricity, the present system is meant to improve the occupant's experience, comfort, and safety, provide the potential to reduce electrical consumption in the monitored environment of the whole office, floor or building by providing actual data about energy consumption to take action to reduce electricity usage. The system enables managers to hold users accountable for their energy use, when often they do not have a direct incentive. The system can be positive (reward users for good behaviour). However, the system can be used to disincentivise poor energy usage behaviour. For example, an employer may force the employee to partake in energy saving tasks as part of their contract of employment. Therefore, poor energy discipline (energy wasting behaviours) like leaving lights on overnight or boiling kettle with too much water for one cup of tea or any mix of these, can be detected and addressed.

FIG. 6C shows a method 600 according to some embodiments herein. The method may be performed by an apparatus such as the apparatus 300 described above. The method 600 is a method for monitoring electrical load in a building, the building having a primary electricity supply that is split into a plurality of individual electrical circuits, as described above. In brief, the method comprises: in step 602, receiving a signal from a first sensing circuit of an electrical load on a first electrical circuit of the plurality of individual electrical circuits, wherein the signal has a sampling rate of at least 18 kHz. The signal may be obtained e.g. using the apparatus illustrated in FIG. 1C described above, and the details therein will be appreciated to apply equally to the method 600. In step 604, the method 600 comprises determining one or more loads that are connected to the first electrical circuit from the signal from the first sensing circuit. In step 606, the method comprises determining a location of a user in the building. This step can be performed using any of the methods described above (e.g. such as wi-fi triangulation or similar). In step 608, the method comprises sending a recommendation to the user to perform an action with respect to one or more loads in the vicinity of the location of the user to i) reduce the energy consumption of the building; ii) manage the health of the one or more loads in the vicinity of the location of the user; and/or iii) perform maintenance on the one or more loads in the vicinity of the location of the user.

There is thus provided a non-intrusive recommender system. It is noted that the high sampling rates and circuit-level monitoring allow for the derivation of improved recommendations, such as those related to appliance health and the like.

The system satisfies the needs of their target audience, makes the interaction with the building management system more efficient and easier and improves occupant comfort conditions. The solution focuses on the building energy management system, which monitors and controls the building energy needs and ensures economical running of the building. Also, the solution provides contextualised green incentivisation and gamification for building occupants who are supposed to be the end-users of the system, to involve them and encourage them to use the solution and engage in energy saving actions or the like to have best practice, such as reduce wasted etc. Through enhanced monitoring, individualisation of consumption profile (individual load profiling) can be determined.

The present embodiment differs from known products at least by the following features:
The recommended system is based on the data collected from sensors and devices in the office. This functionality includes AI (artificial Intelligence) and ML (machine Learning) which help to collect and analyse data, teach the system and create specific, individualised and contextualised recommendations for users.
The interaction with existing systems is such that the system can be retrofitted to existing electrical supply systems.
The rewarding system that helps to engage users to modify user behaviour such that they can monitor and change their energy consumption in the office.
The opportunity to combine different functionalities besides a BEMS.
Minigames. This functionality helps to increase engagement with end-users by retaining existing end-users and attracting new ones. These games include competitive elements, which encourage users to change their interaction behaviour with appliances and use the application with interest and perform various tasks. This can lead to rewards and achievements being provided.
Time-based acceptance of ‘mini game’ to individualise load reduction-turning load on/off.
The ability to deduce many sub-circuit-loads in the building (instead of seeing simply aggregate time series consumption by each circuit.)
Low power device recognition.
Can show historical individual disaggregated loads including time and type (inductive, resistive, capacitive) and determine the type of appliance compared to dataset. See design presentation dashboard slide. Like a log, record, register.
Geofencing of areas not to be monitored and attribution of rewards. Individualisation, and accountability of user's energy footprint.
Application to other firms of activity for example green commuting using Strava/whoop integration, or waste build up in a smart bin for instance. In fact, any other data input related to ESG performance can be monitored and associated with users. (Aggregated ESG related data for user profiling).
The analysis of data provides Individualisation, context-awareness, and micro moments of activity.
Touchpoint plotting—Each load type (icon). It is possible to review electrical consumption of the top 10 (most common) appliances, for example laptop chargers, available and attribute them to the laptop charger icon. So, when the user places the icon on the floorplan and potentially routes it to the known circuit. It is telling the system to expect that number of devices and those potential load signature features.
Manual training snapshot. Fixing, tagging load signature. Setting a baseload for the floorplate when everything possible is turned off (can be done on a circuit-by-circuit level so does not need to be carried out during out of office working hours).
Specify sum of incentive pot. The saving and incentive level can be automatically determined based on the load event total Watt/Kw amount and rate.
Accept or ignore user behaviour trains the system. The system can monitor and provide recommendations such as energy saving recommendations.
Demand response gamification/related to the system. For example, deferred use of appliances, to take advantage of different electrical tariffs, for example setting a dishwasher to turn on late at night in order to use a lower electricity night tariff.
The system can operate without manual intervention from a user (passive from user perspective). The user does not need to open the app to participate.
The electrical loads (icons) themselves may be geofenced, as well as the specified areas such as lift and stairs. This enables the passive tracking of users without them using their phone. By plotting the touchpoints, the position on the floorplate model of that specific appliance is assigned.

### APPENDIX—ELECTRICAL CIRCUIT SENSING STUDY

This study answers the questions regarding the non-intrusive ability to differentiate individual turned-on domestic and commercial electric appliances via analyzing the ripple introduced by their operation to the electric line. The purpose of being able to identify each individual appliance is to measure their unique power consumption and take necessary action.

This study addressed the following questions:
1. Is it technically possible to measure individual appliances' current curve signatures?
2. Is it technically possible to distinguish individual appliances' current curve signatures (CCS further on)?
3. What measuring approach is best suited for such a task?
4. What sampling rate is required to decisively capture a single-running CCS?
5. What sampling rate is required to decisively capture a single CCS with multiple appliances running?
6. What appliance power consumption level is definitive enough to be identifiable, if applicable?
7. What is the likely number of simultaneously running appliances that would allow for individual identification within a different load type group?
8. What is the likely number of simultaneously running appliances that would allow for individual identification within a same load type group?
9. What might be the typical data payload for such an application?
10. What hardware might be suitable for this task?

### The Test Bench Configuration and Prerequisites

For the purpose of this study the following conditions were met:
1. All experiments were done in a typical concrete-wall multi-story residential building with all the typical RF and line noise present. No attempt was made to filter out any such noise.
2. The power line under investigation was single-phase 230V AC 50 Hz, though only Live and Neutral lines were used, PE wire wasn't included in this study.
3. The appliances participating in the experiment are a mix of new and used items for the sake of experiment.

The test bench itself was built to imitate the power consumption meter usually installed in the distribution box at the point power lines are making it into the apartment/office. Two measuring methods were used: via the shunt 0.1 Ohm resistor in series with all tested load and a ferromagnetic core choke of 1.1 Ohm coil resistance and 33 μH inductance, placed over the line in its' opening to act as a current transformer. The line wires are both 1 mm² copper solid uninsulated wire.

The sensing circuit is shown in FIG. 11.

The oscilloscope probes were connected across the shunt resistor for channel 1 and to the choke coil leads for channel 2. The yellow coil at the input of the circuit is a separate current transformer for the measuring head of a VA-meter. Two white dotted wires are VA-meter 220V AC power.

### Equipment Used in the Experiment:

1. OWON 1025i Digital 2-Channel USB Isolated Oscilloscope

| Model | VDS1022I | | VDS1022 | |
|---|---|---|---|---|
| Bandwidth | 25 | | MHZ | |
| Channel | 2 + 1 (multi) | | | |
| Sample Rate | 100MSa/s | | | |
| Horizontal Scale (s/div) | 5 ns/div~100 s'div, step by 1~2~5 | | | |
| Record Length | 5K | | | |
| Max Input Voltage | 400 V (PK-PK) | | 40 V (PK-PK) (DC + AC, | |
| | DC + AC, PK-PK) | | PK-PK) | |
| Vertical Resolution (A/D) | 8 bits (2 channels simultaneously) | | | |
| Model | VDS1022I | VDS1022 | VDS2052 | VDS206 |

| | | | |
|---|---|---|---|
| Vertical Sensitivity | 5 mV/div~5 mV/div | 2 | mV/div |

| Trigger Type | | Edge, Pulse, Video, Slope, Alternate | |
|---|---|---|---|
| Trigger Mode | | Auto, Normal, Single | |
| Acquisition Mode | | Sample, Peak Detect, and Average | |
| Waveform Math | | +, −, ×, ÷, invert, FFT | |
| Communication Interface | | USB 2.0 (isolation) | USB2.0 |
| | Signal Type | Synchronised input/output, Pass/Fail, external trigger input | |
| Multi- | Level | TTL | |
| function | Standard | | |
| Interface | | | |

| Power Supply | 5.0 V/1 A | | |
|---|---|---|---|
| Power Consumption | ≤2.5 W | ≤6.5 | W |

| | | |
|---|---|---|
| Dimensions (W × H × D) | 170 × 120 × 18 (mm) | 190 × 12 |

| | | |
|---|---|---|
| Device Weight | 0.26 | kg |

2. 100 W adjustable DC electronic load:
3. Extension multiple socket distributor with a separate neon-lighted switch, allowing to turn all loads on/off at once:
4. Phone smart charger, capable of QuickCharge 3 and outputs of 5, 9, and 12 volts:
5. Laptop 19 v 90 W power supply:
6. Lenovo ThinkPad x120e laptop:
7. CFL lamps. Two same brand YOM 16 W lamps, Lamp A is new, Lamp B is used:
8. Rowenta Infini Pro 2000 W hair dryer.

### Measurements

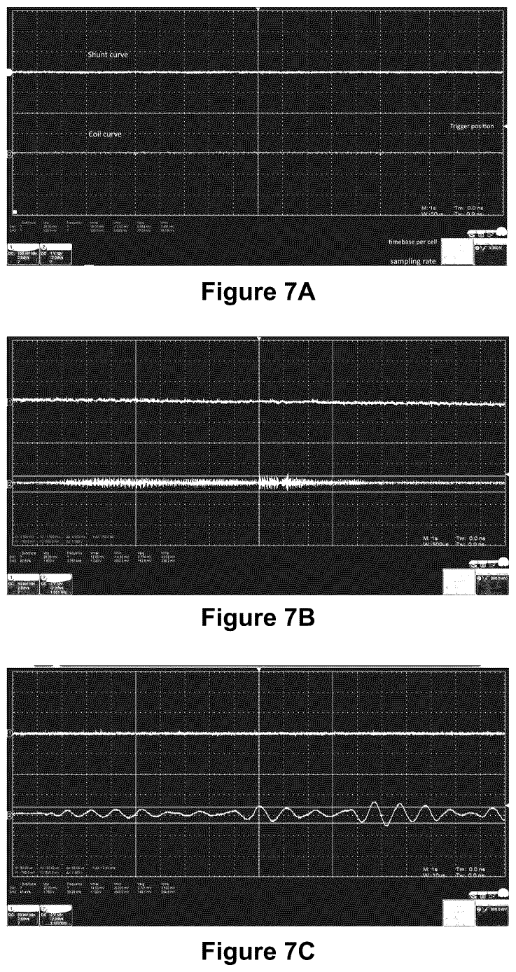

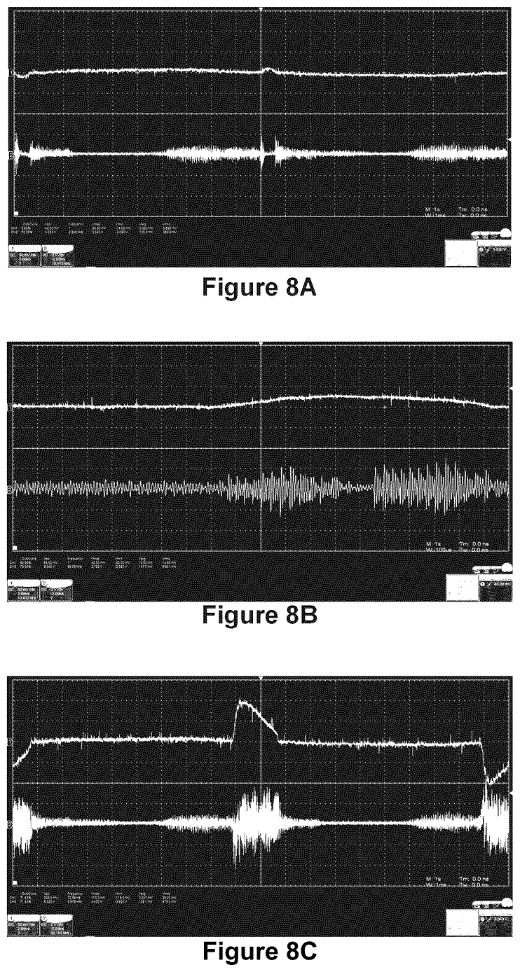

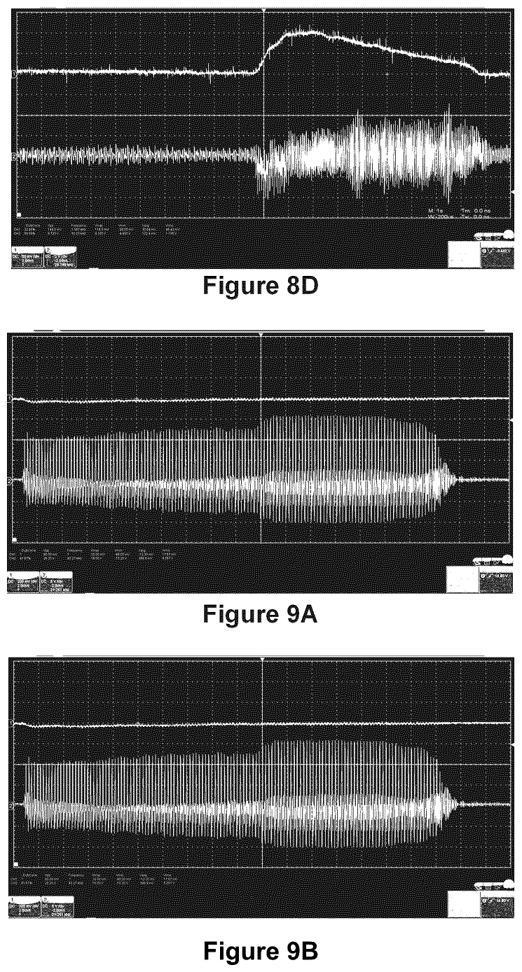

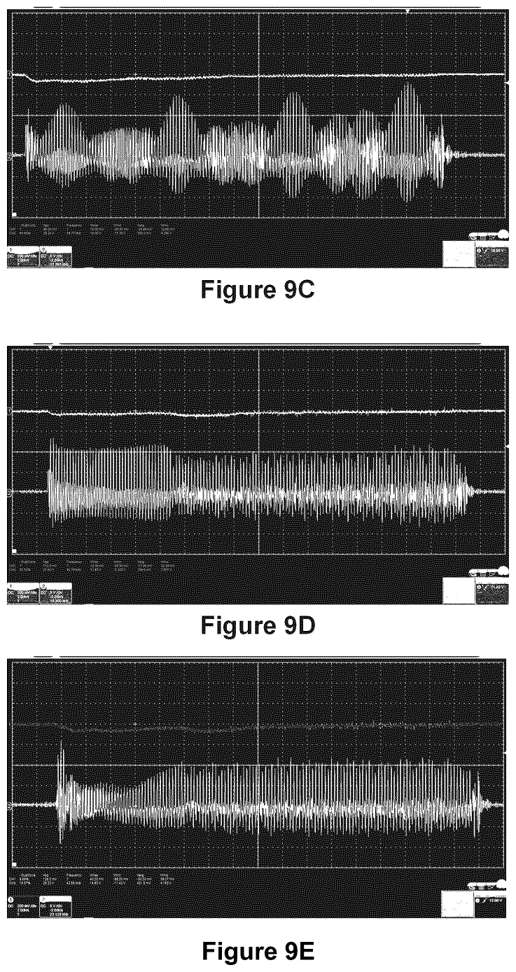

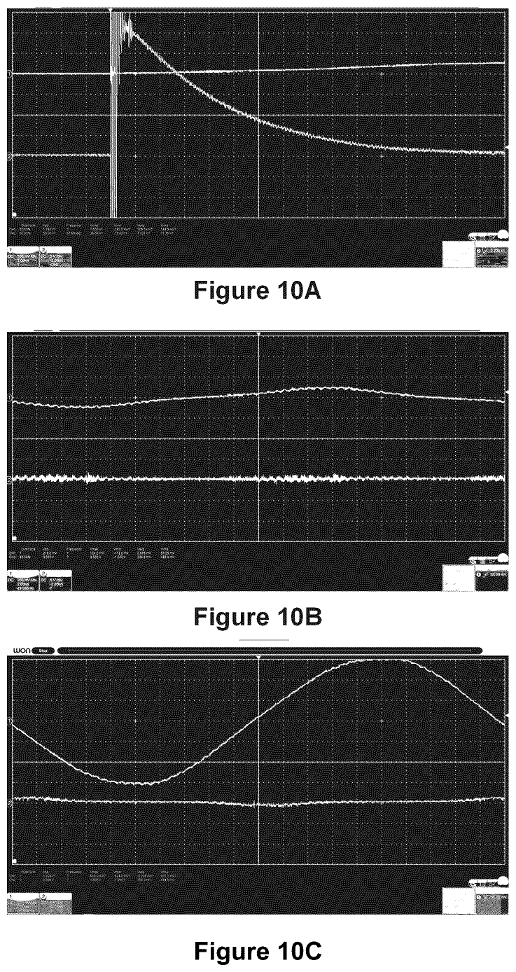

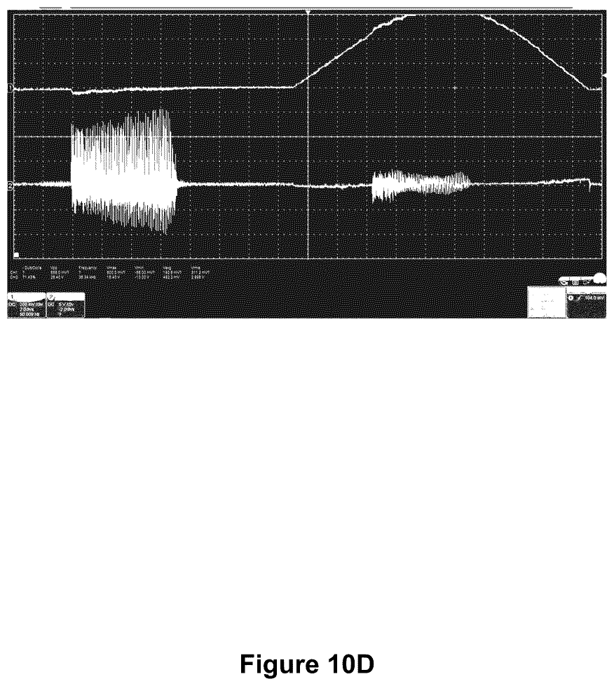

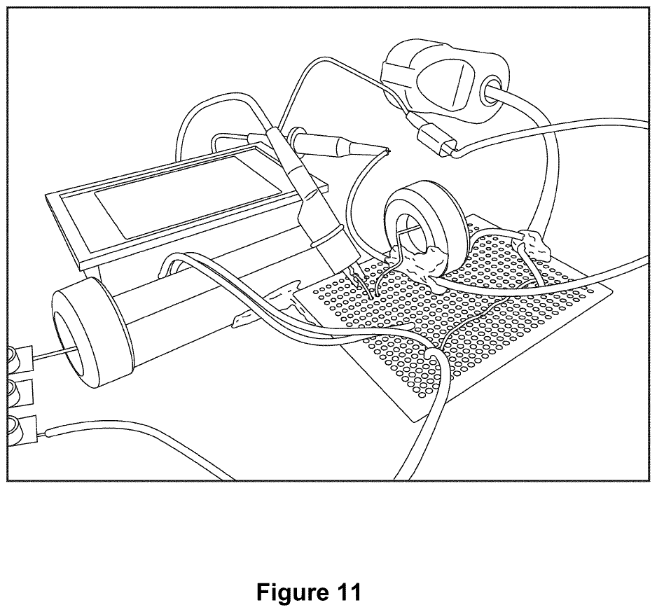

FIG. 7A shows an Idle Baseline, no load. Here and further on the Channel 1 red curve (uppermost on the oscilloscope) represents the measurements taken across the shunt resistor, Channel 2 yellow curve (lowermost on the oscilloscope) is an output from coil leads.

FIGS. 7B and 7C show the results in the above situation to illustrate the sensed signal with just powering the empty extension outlet, which has a small <1 W light in the switch. The screen grabs in FIGS. 7B and 7C shows the signal at different time resolutions, from 500 μs/div (as shown in FIG. 7B) to 10 μs/div (as shown in FIG. 7C):

Note the required samples per second indication to build each of the graphs. Also, the shunt method alone is not definitive enough even at 25 million samples/sec for low power appliance.

Results for the sensing circuit when a 90 W 19V laptop power supply was in the circuit at different loads and resolutions:

FIG. 8A shows a 1 Watt load 1 ms/div resolution, 250K Samples/sec

FIG. 8B shows a 1 Watt load 0.1 ms/div resolution, 2.5M Samples/sec

FIG. 8C shows a 30 Watt load 1 ms/div resolution, 250K Sa/sec

FIG. 8D shows a 30 Watt load 0.2 ms/div resolution, 1.25M Sa/sec. Here it can be seen that the shunt curve is becoming more descriptive at higher power consumption levels, 5 Watts being the threshold on capacitive loads.

Results for the sensing circuit when two identical CFL Lamps rated 16 W-were tested:

FIG. 9A shows CFL Lamp A, at 0.2 ms/div resolution and FIG. 9B shows CFL Lamp B, 0.2 ms/div. Note the difference in signature between the two, being the same brand and year.

FIG. 9C shows Lamp A and Lamp B turned on together, at 0.2 ms/div resolution.

FIG. 9D shows CFL lamp A together with the phone charger, loaded at 5 Watt, at 0.2 ms/div resolution.

FIG. 9E shows CFL lamps A&B together with the phone charger, loaded at 5 Watt, at 0.2 ms/div resolution.

These figures show that all these 3 devices working together have their waveforms summed.

FIG. 10A shows a turn-on signature for a hair dryer (motor only) which has an inductive and restive load. The signature is shown on a scale of 0.2 ms/division. It is to be appreciated that transient currents of appliances can be off the chart for the brief periods of time and so the sensing circuit would employ filters in order not to risk damaging the measuring equipment but still enables another type of device signature to be captured.

FIG. 10B shows the waveform of an idling hair dryer at a 1 ms/div resolution, where the inductive load shows more variation than the resistive load.

FIG. 10C shows the waveform at 1 ms/div resolution when the hairdryer hearer is turned on. With little inductive load and big resistive load at the same time, the working signature taken via the coil is becoming less and less definitive, whilst the shunt curve gains a lot of amplitude.

FIG. 10D shows the waveform at 1 ms/div resolution when another kind of electrical load, like a CFL Lamp A is added to the circuit. Here both the shunt and choke waveforms change dramatically providing a unique signature for detection.

### Conclusions of Study

1. It is technically possible to measure individual appliances' current curve signatures.
2. It is technically possible to distinguish individual appliances' current curve signatures (CCS further on).
3. The measuring approach best suited for each task differs with different types of load. Resistive loads show much smaller ripple on the current transformer but have more defined signatures using the shunt resistor, while inductive/capacitive loads show much less imprint on the shunt resistor and better-defined signatures on the current transformer. Accordingly, both resistive and inductive sensing should be used in the sensing circuit to distinguish a greater range of different electrical load signatures, for example of different appliances.
4. The sampling rate required to decisively capture a single-running CCS (namely one device (electrical load) on a single circuit) is 500K samples/sec for low-power devices (<5 W) and 250K samples/sec for other higher-powered devices.
5. The sampling rate required to decisively capture a single CCS with multiple appliances running (namely multiple devices on a single circuit) is 1M to 5M samples/sec (namely 1 MHz to 5 Mhz).
6. The sensing circuit can detect an identifiable signature in an appliance having a power consumption level which is less than 1 W, given the sampling rate of over 1M samples/sec.
7. The likely number of simultaneously running appliances that would allow for individual identification within a different load type group is about 10-15.
8. The likely number of simultaneously running appliances that would allow for individual identification within a same load type group is about 5-10.
9. A typical data payload for such an application would be a stream containing: datalogger ID, time mark and voltage level all at a chosen sampling rate.
10. Hardware that would be suitable for data logging the sampled data and optionally edge processing that data would be a microcontroller with local memory such as the Espressif ESP32, for example.

What is claimed is:

1. An apparatus for monitoring electrical load in a building, the apparatus comprising:
a first sensing circuit configured to sense electrical load in a first electrical circuit in the building; and
an analogue to digital converter, ADC, configured to measure the electrical load sensed by the first sensing circuit at a sampling rate greater than or equal to 18 kHz.

2. The apparatus of claim 1, wherein the sampling rate is between about 1 MHz and about 5 MHz or between about 1 MHz and about 2 MHz.

3. The apparatus of claim 1, wherein the first sensing circuit comprises a ferrite core that can be affixed around a portion of the first electrical circuit; and
a coil that winds around at least a portion of the ferrite core, wherein the coil non-obtrusively detects current fluctuations in the portion of the first electrical circuit.

4. The apparatus of claim 1, further comprising an auto-gain adjuster.

5. The apparatus of claim 1, wherein the sampling rate is set dependent on:
a number of loads connected to the first electrical circuit; and/or
load characteristics of the loads connected to the first electrical circuit.

6. The apparatus of claim 5, wherein the sampling rate is set to a higher rate when a first number of appliances are connected to the first electrical circuit compared to when a second number of appliances are connected to the first electrical circuit, wherein the first number of appliances is greater than the second number of appliances.

7. The apparatus of claim 6, wherein the sampling rate is set higher when there is more than one appliance of a same type on the first electrical circuit compared to when each appliance on the first electrical circuit is of a different type or when one or more of the appliances connected to the first electrical circuit are low load appliances compared to when the appliances are high load appliances.

8. A computer-implemented method for monitoring electrical load in a building, the method comprising:
receiving a signal from a first sensing circuit of an electrical load on a first electrical circuit in the building, wherein the signal has a sampling rate of at least 18 kHz; and
determining one or more loads that are connected to the first electrical circuit from the signal from the first sensing circuit.

9. The computer-implemented method of claim 8, wherein the signal has a sampling rate of between about 1 MHz and about 5 MHz or between about 1 MHz and about 2 MHz.

10. The computer-implemented method of claim 8 further comprising:
determining a number of loads connected to the first electrical circuit and/or load characteristics of the one or more loads connected to the first electrical circuit; and
sending an instruction to an analogue to digital converter (ADC) to set the sampling rate of the ADC, according to the determined number of loads and/or the load characteristics.

11. The computer-implemented method of claim 8, wherein determining one or more loads comprises:
determining one or more appliances on the first electrical circuit based on load signatures in the received signal using mixed deep learning models, Fast Fourier Transform (FFT), and/or techniques related to Nonintrusive Load Monitoring (NILM); wherein a load signature corresponds to a change in electrical load on the first electrical circuit when an appliance is activated.

12. The computer-implemented method of claim 8, wherein the determining comprises using a model trained using a machine learning process to determine the one or more loads from the signal from the first sensing circuit;
wherein using a model comprises:
determining one or more sub-signals in the signal from the first sensing circuit, corresponding to one or more loads connected to the first electrical circuit; and
classifying the one more sub-signals according to load type.

13. The computer-implemented method of claim 8, wherein the determining comprises using a model trained using a machine learning process to determine the one or more loads from the signal from the first sensing circuit;
wherein the model classifies the one or more sub-signals based on transients and harmonics in the one or more sub-signals.

14. The computer-implemented method of claim 8, wherein the determining comprises using a model trained using a machine learning process to determine the one or more loads from the signal from the first sensing circuit;
and wherein the method further comprises:
determining an unknown sub-signal in the signal;
sending a request for a user to supply a first user input identifying an appliance associated with the unknown sub-signal;
receiving the first user input identifying the unknown sub-signal; and
using the label and the unknown sub-signal as training data with which to further train the model.

15. The computer-implemented method of claim 8, wherein:
the determining comprises using a model trained using a machine learning process to determine the one or more loads from the signal from the first sensing circuit; and
the model further takes as input data relating to an appliance age, temperature, humidity and/or other environmental conditions.

16. The computer-implemented method of claim 8 further comprising:
obtaining acoustic signatures in the physical vicinity of the first circuit; and
predicting locations of the one or more appliances in the building, by matching the one or more appliances to the acoustic signatures.

17. The computer-implemented method of claim 8 further comprising:
obtaining mobile device data of a user in the physical vicinity of the first circuit; and
predicting locations of the one or more appliances in the building, from the mobile device data.

18. The computer-implemented method of claim 17 further comprising:
providing a recommendation to the user of an action that could be taken by the user to i) reduce energy consumption of the first electrical circuit, ii) manage health of the one or more loads in the vicinity of the location of the user; and/or iii) perform maintenance on the one or more loads in the vicinity of the location of the user by:
matching the locations of the one or more appliances to a location of the user; and
determining an action that might be performed by the user on the matched appliances.

19. The computer-implemented method of claim 8, further comprising determining that a first load of the one or more loads is damaged or malfunctioning, according to:
electrical noise detected in a signature of the first load; and/or
a change in a signature of the first load over time.

20. Computer readable instructions which, when executed by one or more processors, cause the one or more processors to perform a method comprising:
receiving a signal from a first sensing circuit of an electrical load on a first electrical circuit in a building, wherein the signal has a sampling rate of at least 18 kHz; and
determining one or more loads that are connected to the first electrical circuit from the signal from the first sensing circuit.
